(19) United States
(12) Patent Application Publication
(10) Pub. No.: US 2026/0144164 A1
(43) Pub. Date: May 21, 2026

(54) POWER MODULES WITH VERTICALLY-ORIENTED POWER DIES

(71) Applicant: Monolithic Power Systems, Inc., San Jose, CA (US)

(72) Inventors: Ting GE, San Jose, CA (US); Yingxin ZHOU, San Jose, CA (US); Yong HU, San Jose, CA (US)

(21) Appl. No.: 19/451,874

(22) Filed: Jan. 16, 2026

Related U.S. Application Data
(63) Continuation-in-part of application No. 18/983,736, filed on Dec. 17, 2024.
(60) Provisional application No. 63/687,182, filed on Aug. 26, 2024.

(51) Int. Cl. H10W 90/26; H02M 3/00; H10D 1/20; H10D 80/20; H10D 80/30; H10W 90/00

(52) U.S. Cl. CPC H10W 90/26; H02M 3/003; H10D 1/20; H10D 80/213; H10D 80/215; H10D 80/30; H10W 90/401; H10W 90/724; H10W 90/726

(57) ABSTRACT

Disclosed are power modules that include first and second power dies, each having a gate driver and a pair of transistors, together with an inductor structure formed from first and second inductor coils wound around a shared magnetic core. Each coil has an end electrically connected to a common output-voltage node and another end electrically connected to a switch node of the corresponding power die. The inductor structure has an outer profile defining a top side, a bottom side, opposing wide sides, and opposing narrow sides, with the first ends of the coils disposed along the bottom side and offset from one another, and the second ends disposed on different ones of the narrow sides.

### CROSS-REFERENCE TO RELATED APPLICATIONS

The present application is a continuation-in-part of U.S. application Ser. No. 18/983,736, filed on Dec. 17, 2024, which claims the benefit of U.S. Provisional Application No. 63/687,182, filed on Aug. 26, 2024. These related applications are incorporated herein by reference in their entirety.

### TECHNICAL FIELD

The present application is directed generally to electrical circuits, and more particularly to power modules.

### BACKGROUND

Power modules include the electrical circuits of a power converter, such as a DC-DC converter or AC-DC converter. To reduce footprint, a power module may incorporate a DrMOS module, which integrates a gate driver and metal-oxide-semiconductor field-effect transistors (MOSFETs) in a single package. Power modules are compact, making them well-suited for space-critical power converter applications.

Current density is the electrical current per unit area of the power module. For instance, a two-phase power module measuring 9 mm×10 mm can output 65 A, resulting in a current density of approximately 0.72 A/mm². Achieving a target current density of 4 A/mm² exceeds the capability of current DrMOS modules. Enhancing the current density of power modules is critical to meeting the demands of high-current power converter applications.

### BRIEF SUMMARY

In one embodiment, a power module includes first and second power dies, each having a gate driver and a pair of transistors, together with an inductor structure having first and second inductor coils wound one turn each around a shared magnetic core. The first inductor coil has a first end connected to an output-voltage (VOUT) node and a second end connected to a switch node of the first power die, and the second inductor coil has a first end connected to the VOUT node and a second end connected to a switch node of the second power die. The inductor structure defines an outer profile with a top side and a bottom side, and the first ends of the two inductor coils are arranged along the bottom side in positions that are offset from one another along its length.

In another embodiment, an inductor structure for a power module includes first and second inductor coils, each having respective first and second ends, and a magnetic core that is shared by both coils. Each coil is wound on the magnetic core for a single turn. The inductor structure defines an outer profile having a top side and a bottom side, with the first ends of the two inductor coils positioned along the bottom side in locations that are offset from one another along its length.

In yet another embodiment, a power module includes first and second power dies, each comprising a gate driver and a pair of transistors, together with an inductor structure that incorporates first and second inductor coils wound one turn each around a shared magnetic core. The first inductor coil has a first end connected to a VOUT node and a second end connected to a switch node of the first power die, while the second inductor coil has a first end connected to the VOUT node and a second end connected to a switch node of the second power die. The inductor structure defines an outer profile having a top side, a bottom side, opposing wide sides, and opposing narrow sides, with the narrow sides being narrower than the wide sides. The first ends of both coils are located on the bottom side, and the second ends of the coils are positioned on different ones of the opposing narrow sides.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. For ease of illustration, not every instance of a repeated element is labeled in the drawings; such elements are readily identifiable from the drawings and their context. The drawings are not necessarily to scale

FIG. 1 shows an electrical schematic diagram of a power converter, in accordance with an embodiment of the present invention.

FIG. 2 shows a physical layout diagram of a power module with a vertically-oriented power die, in accordance with an embodiment of the present invention.

FIGS. 3 and 4 show physical layout diagrams of power modules with vertically-oriented power dies, in accordance with embodiments of the present invention.

FIG. 5 shows a physical layout diagram of a power module with a vertically-oriented power die, in accordance with an embodiment of the present invention.

FIG. 6 shows a first planar side of a multilayer substrate of the power module of FIG. 5, in accordance with an embodiment of the present invention.

FIG. 7 shows a second planar side of the multilayer substrate of the power module of FIG. 5, in accordance with an embodiment of the present invention.

FIG. 8 shows top and bottom ends of the power module of FIG. 5, in accordance with an embodiment of the present invention.

FIG. 9 shows a physical layout diagram of a power module with a vertically-oriented power die, in accordance with an embodiment of the present invention.

FIG. 10 shows a three-dimensional (3D) view of the power module of FIG. 9, in accordance with an embodiment of the present invention.

FIG. 11 shows a transparent 3D view of the power module of FIG. 9, in accordance with an embodiment of the present invention.

FIG. 12 shows a second planar side of the multilayer substrate of the power module of FIG. 9, in accordance with an embodiment of the present invention.

FIG. 13 shows a physical layout diagram of a power module with a plurality of vertically-oriented power dies, in accordance with an embodiment of the present invention.

FIG. 14 shows a physical layout diagram of a power module with a vertically-oriented power die, in accordance with an embodiment of the present invention.

FIG. 15 shows a planar side of the multilayer substrate of the power module of FIG. 14, in accordance with an embodiment of the present invention.

FIG. 16 shows a physical layout diagram of a power module with a plurality of vertically-oriented power dies, in accordance with an embodiment of the present invention.

FIG. 17 shows a 3D view of the power module of FIG. 16, in accordance with an embodiment of the present invention.

FIGS. 18, 19A, 19B, 20A, and 20B show transparent 3D views of components of the power module of FIG. 16, in accordance with an embodiment of the present invention.

FIG. 21 shows a 3D view of inductor coils, in accordance with an embodiment of the present invention.

FIG. 22 shows a 3D view of pads, in accordance with an embodiment of the present invention.

FIG. 23 shows a planar side of the power module of FIG. 16, in accordance with an embodiment of the present invention.

FIG. 24 shows a bottom end of the power module of FIG. 16, in accordance with an embodiment of the present invention.

FIG. 25 shows a physical layout diagram of a power module with a plurality of vertically-oriented power dies, in accordance with an embodiment of the present invention.

FIG. 26 shows a 3D view of the power module of FIG. 25, in accordance with an embodiment of the present invention.

FIG. 27 shows a 3D view of a power module with a plurality of vertically-oriented power dies, in accordance with an embodiment of the present invention.

FIG. 28 shows a physical layout diagram of the power module of FIG. 27, in accordance with an embodiment of the present invention.

FIG. 29 shows a top end of the power module of FIG. 27, in accordance with an embodiment of the present invention.

FIG. 30 shows a side of the power module of FIG. 27, in accordance with an embodiment of the present invention.

FIG. 31 shows a 3D view of an inductor structure, in accordance with an embodiment of the present invention.

FIG. 32 shows an exploded view of the inductor structure of FIG. 31, in accordance with an embodiment of the present invention.

FIG. 33 shows a bottom view of the inductor structure of FIG. 31, in accordance with an embodiment of the present invention.

FIG. 34 shows a wireframe view of the inductor structure of FIG. 31, in accordance with an embodiment of the present invention.

FIG. 35 shows a transparent 3D view of the inductor structure of FIG. 31, in accordance with an embodiment of the present invention.

FIG. 36 shows another transparent 3D view of the inductor structure of FIG. 31, in accordance with an embodiment of the present invention.

FIG. 37 shows a 3D view of an inductor structure, in accordance with an embodiment of the present invention.

FIG. 38 shows a wireframe view of the inductor structure of FIG. 37, in accordance with an embodiment of the present invention.

FIG. 39 shows a transparent 3D view of the inductor structure of FIG. 37, in accordance with an embodiment of the present invention.

FIG. 40 shows another transparent 3D view of the inductor structure of FIG. 37, in accordance with an embodiment of the present invention.

FIG. 41 shows a 3D view of an inductor structure, in accordance with an embodiment of the present invention.

FIG. 42 shows an exploded view of the inductor structure of FIG. 41, in accordance with an embodiment of the present invention.

FIG. 43 shows a wireframe view of the inductor structure of FIG. 41, in accordance with an embodiment of the present invention.

FIG. 44 shows a 3D view of an inductor structure, in accordance with an embodiment of the present invention.

FIG. 45 shows an exploded view of the inductor structure of FIG. 44, in accordance with an embodiment of the present invention.

FIG. 46 shows a wireframe view of the inductor structure of FIG. 44, in accordance with an embodiment of the present invention.

FIG. 47 shows a 3D view of an inductor structure, in accordance with an embodiment of the present invention.

FIG. 48 shows a wireframe view of the inductor structure of FIG. 47, in accordance with an embodiment of the present invention.

### DETAILED DESCRIPTION

In the present disclosure, numerous specific details are provided, such as examples of electrical circuits, components, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

Power modules must deliver increasingly higher current densities to meet the escalating power demands of central processing units (CPUs), graphics processing units (GPUs), and other components used in artificial intelligence (AI) applications. Traditional two-phase power modules with a 9 mm×10 mm footprint and a maximum current output of 130 A are insufficient to achieve the current density required by the next generation of AI platforms.

Inductors and dies of power transistors typically occupy most of the area of a power module. The power transistors may be power MOSFETs or power field-effect transistors (FETs). Inductors and dies of power transistors may be stacked to increase current density, such as in sandwich and inductor-on-top configurations. Embodiments of the present further increase current density by utilizing a vertically-oriented power die configuration.

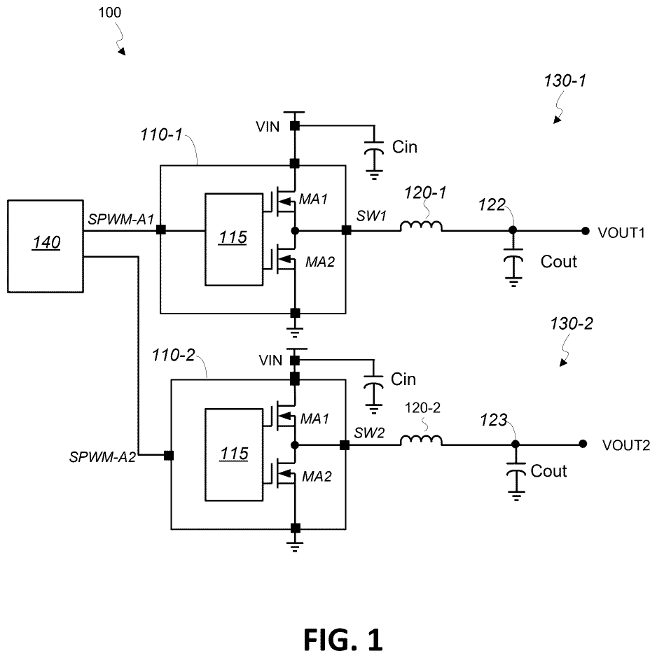

FIG. 1 shows an electrical schematic diagram of a power converter 100, in accordance with an embodiment of the present invention. Components of the power converter 100 may be incorporated in power modules disclosed herein.

In the example of FIG. 1, the power converter 100 has two regulator circuits 130 (i.e., 130-1, 130-2), with each regulator circuit 130 comprising an output inductor 120 (i.e., 120-1, 120-2) and a power stage 110 (i.e., 110-1, 110-2). As will be more apparent below, a power stage 110 may be formed in an integrated circuit (IC) die, which is referred to herein as a power die. The power converter 100 may be implemented using a power module that includes one or more vertically-oriented power dies.

In the example of FIG. 1, a regulator circuit 130 is configured such that the power converter 100 is a buck converter. As can be appreciated, a regulator circuit 130 may also be configured such that the power converter 100 is a boost converter or other type of power converter depending on the application. Each of the regulator circuits 130-1 and 130-2 receives an input voltage VIN to generate an output voltage VOUT (i.e., VOUT1, VOUT2). The output voltages of the regulator circuits 130-1 and 130-2 may be connected together and interleaved to generate a multiphase output voltage. For example, an output voltage node 122 and an output voltage node 123 may be connected together, with each regulator circuit 130 generating a phase of the multiphase power converter. Generally, the power converter 100 may include additional regulator circuits 130 to generate additional phases of a multiphase output voltage or additional separate output voltages. The power converter 100 may also be configured as a single-phase converter by utilizing a single regulator circuit 130.

In the example of FIG. 1, each power stage 110 has a driver 115, a high-side switch MA1, and a low-side switch MA2. In one embodiment, each power stage 110 is a DrMOS module, wherein each of the switches MA1 and MA2 is a MOSFET and the driver 115 is a gate driver that is integrated with the switches MA1 and MA2. In the example of FIG. 1, a power stage 110 has a first node for receiving a PWM signal (SPWM-A1, SPWM-A2), a second node for receiving an input voltage VIN, a third node for connecting to ground, and a switch node SW (SW1, SW2) formed by the pair of switches MA1 and MA2. The drain of the switch MA1 is connected to the input voltage VIN and the source of the switch MA2 is connected to ground. The source of the switch MA1 is connected to the drain of the switch MA2 at the switch node SW. A PWM controller 140 generates PWM signals (SPWM-A1, SPWM-A2). The driver 115 turns the switches MA1 and MA2 ON and OFF in accordance with a corresponding PWM signal to generate the output voltage VOUT.

In the example of FIG. 1, a first end of an output inductor 120 is connected to the switch node SW and a second end of the output inductor 120 is connected to the output voltage VOUT. Two or more output inductors 120 may be formed by two or more inductor coils that share the same magnetic core. An input capacitor Cin is connected to the input voltage VIN, and an output capacitor Cout is connected to the output voltage VOUT. Each of the input capacitor Cin and output capacitor Cout may comprise a plurality of capacitors that are connected in parallel, for example.

The power converter 100 or other power converters may be implemented using the following power modules. Generally, a power module may include a power stage in the form of a power die, inductors, capacitors, and other components of a power converter. A controller (e.g., FIG. 1, PWM controller 140) may be installed on a motherboard or other substrates that are external to the power module.

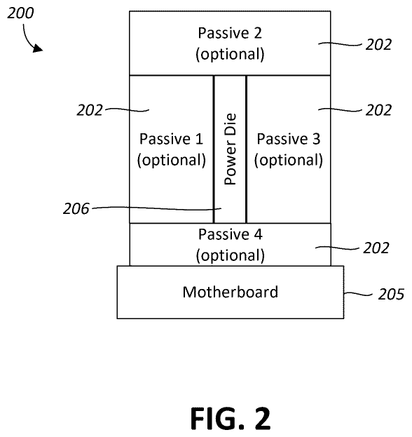

FIG. 2 shows a physical layout diagram of a power module 200 with a vertically-oriented power die 206, in accordance with an embodiment of the present invention. As used herein, the term “physical layout diagram” refers to a schematic representation of the arrangement of components and is not intended to represent precise physical dimensions or proportions. The term “edge” refers to narrower sides, in contrast to planar sides, which have a significantly larger surface area. FIG. 2 shows a side edge of the power die 206.

In the example of FIG. 2, the power module 200 is disposed on a motherboard 205. In one embodiment, the motherboard 205 is a printed circuit board (PCB). The power module 200 is mounted on a component side of the motherboard 205. The motherboard 205 may include additional components that are not shown, such a PWM controller and other components that form a power converter with components of the power module 200.

The power die 206 is vertically-oriented in that the power die 206 is disposed vertically relative to the plane of a base substrate that supports the power module, such as the motherboard 205 in the example of FIG. 2. The bottom edge of the power die 206 faces toward the plane of the base substrate and the plane of the power die 206 is perpendicular relative to the plane of the base substrate. In this orientation, the power die 206 is positioned on its bottom edge, standing upright, rather than lying flat on the plane of the base substrate.

It is to be noted that the plane of the power die 206 does not need to be perfectly perpendicular to the plane of the base substrate. More specifically, for purposes of the present disclosure, a power die is considered vertically disposed on the base substrate when the plane of the power die forms an angle within +/−45° of a line that is perpendicular to the plane of the base substrate.

The power module 200 may optionally include passive components 202, which may include inductors, capacitors, resistors, heatsinks, substrates, etc. The passive components 202 may be placed in the vicinity of the power die 206, such as on a top edge, bottom edge, planar sides, and/or side edges of the power die 206.

Generally, a power die 206 is a die of a power transistor, such as a power MOSFET or power FET. In one embodiment, a power die 206 is the die of a DrMOS module comprising a gate driver and a pair of MOSFETs. A single power die 206 may thus generate a single phase of an output voltage. Adding more power dies 206 allows the power module 200 to generate additional output voltage phases.

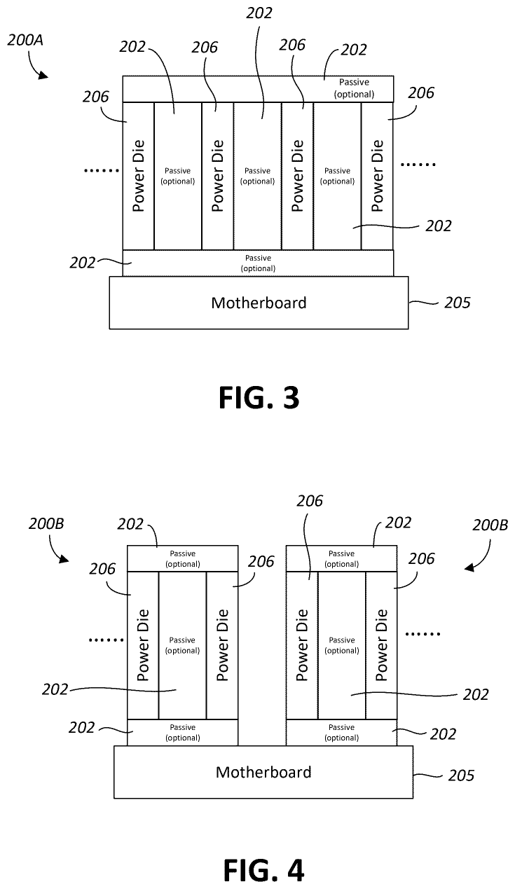

FIGS. 3 and 4 show physical layout diagrams of power modules 200A and 200B, respectively, with vertically-oriented power dies 206, in accordance with embodiments of the present invention. FIGS. 3 and 4 show side edges of the power dies 206. The bottom edges of the power dies 206 face toward the motherboard 205.

Similar to the power module 200, each of the power modules 200A and 200B includes power dies 206 that are disposed vertically on the motherboard 205 and may optionally include passive components 202. FIG. 3 illustrates an example in which the power module 200A includes four power dies 206, to allow for increased output current or four output voltage phases per power module. FIG. 4 illustrates an example in which the power module 200B includes two power dies 206, thereby providing two output voltage phases per power module. Using two power modules 200B thus allows for the generation of four output voltage phases.

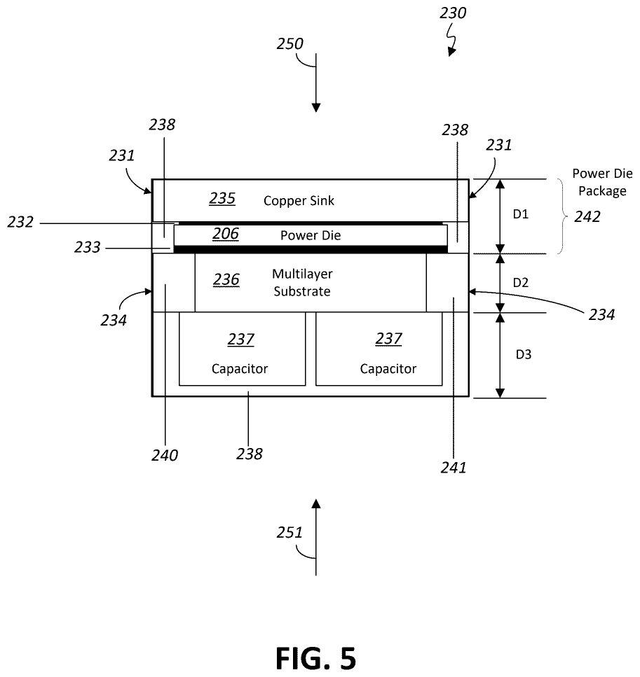

FIG. 5 shows a physical layout diagram of a power module 230 with a vertically-oriented power die 206, in accordance with an embodiment of the present invention. FIG. 5 shows a side edge of the power die 206. The power module 230 is depicted horizontally in FIG. 5 for illustration purposes. In practice, the power module 230 is disposed vertically relative to a base substrate that supports the power module 230. In one embodiment, the power module 230 has a dimension D1 of 0.7 mm, a dimension D2 of 0.56 mm, and a dimension D3 of 0.8 mm.

In the example of FIG. 5, a copper sink 235 serves as a heatsink that is attached to a first planar side of the power die 206 by a thermal interface material (TIM) 232, such as a thermal glue. In one embodiment, the power die 206 and the copper sink 235 are packaged together in a power die package 242, with a planar side of the copper sink 235 exposed to the environment on an outermost surface of the power module 230 for thermal management purposes. Empty regions in the power module 230 may be filled by molding compound 238.

The second planar side of the power die 206 is attached to a first planar side of a multilayer substrate 236 by contact points 233, such as solder bumps. Capacitors 237 (e.g., size 0402 capacitors) and other passive components may be attached to a second planar side of the multilayer substrate 236. Generally, a multilayer substrate, such as the multilayer substrate 236, may have several layers for incorporating different interconnect structures, passive components, etc. The interconnect structures in the multilayer substrate provide electrical connections between nodes in a power module and nodes that are external to the power module.

Because the power die 206 is vertically-oriented, electrical connections to the power module 230 can be made to the bottom and top ends of the power module 230. Specifically, the multilayer substrate 236 may have wettable sides 240 and 241 on corresponding side edges of the multilayer substrate 236. The wettable sides 240 and 241 provide exposed surfaces 234 for soldering or other electrical connection to the side edges of the multilayer substrate 236. Similarly, to allow the copper sink 235 to serve as an interconnect or node, the copper sink 235 may also have exposed surfaces 231 for soldering on its side edges. The exposed soldering surfaces 231 and 234 facilitate connection to the power die 206 and nodes in the multilayer substrate 236 or other substrate of the power module 230.

FIG. 5 further shows a reference arrow 250 that points toward the first planar sides of the power die 206 and multilayer substrate 236, and a reference arrow 251 that points toward the second planar sides of power die 206 and the multilayer substrate 236.

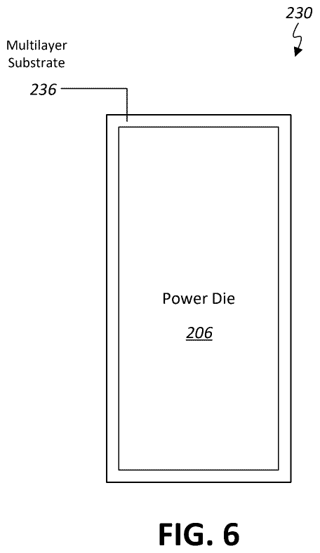

FIG. 6 shows the first planar side of the multilayer substrate 236 of the power module 230, in accordance with an embodiment of the present invention. FIG. 6 represents a view in the direction of the arrow 250 shown in FIG. 5, with the copper sink 235 omitted. As illustrated in FIG. 6, the power die 206 is mounted on the first planar side of the multilayer substrate 236.

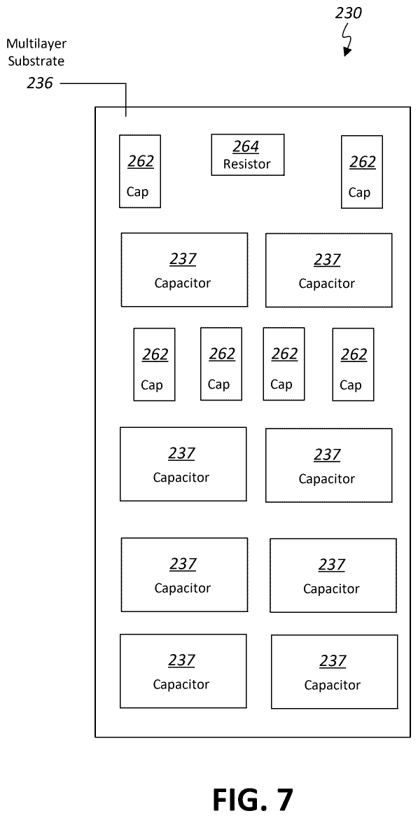

FIG. 7 shows the second planar side of the multilayer substrate 236 of the power module 230, in accordance with an embodiment of the present invention. FIG. 7 represents a view in the direction of the arrow 251 shown in FIG. 5. In one embodiment, the second planar side of the multilayer substrate 236 is a passive component side where passive components, such as capacitors 237 (e.g., size 0402 capacitors), capacitors 262 (e.g., size 0201 capacitors), one or more resistors 264 (e.g., size 0201 resistors), etc. are mounted. In one embodiment, the capacitors 237 are input capacitors of the power converter implemented using the power module 230.

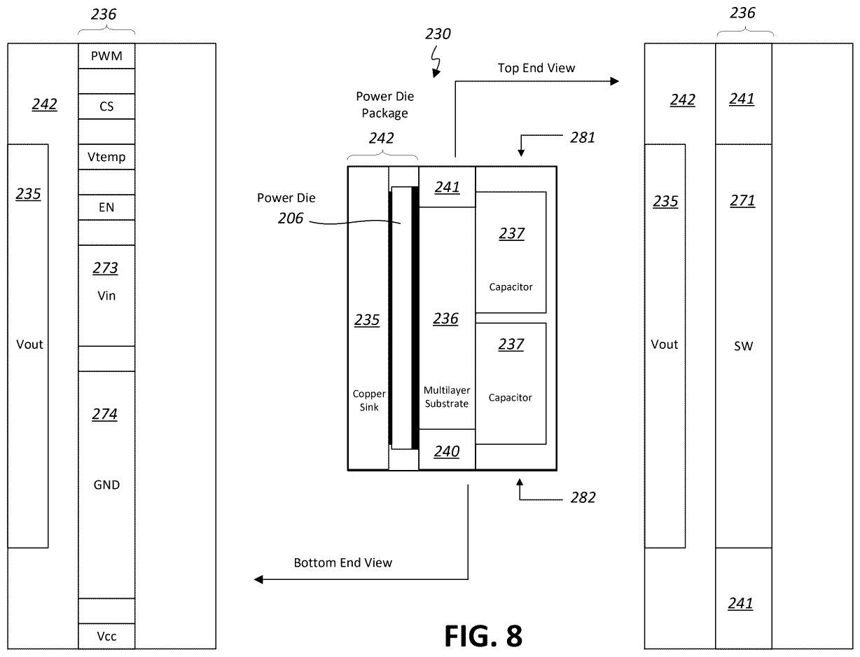

FIG. 8 shows a view of a top end 281 and a view of a bottom end 282 of the power module 230, in accordance with an embodiment of the present invention. As incorporated in an electronic device, the bottom end 282 faces toward a base substrate (not shown) that supports the power module 230. As will be discussed below, an output inductor of a power converter implemented using the power module 230 may be disposed on the top end 281.

On the top end 281 (see right side of FIG. 8), the copper sink 235 is exposed through the power die package 242 to provide an electrical connection to the output voltage VOUT. A pad 271 on a side edge of the multilayer substrate 236 is electrically connected to a switch node SW formed by a pair of MOSFETs of the power die 206. Exposed on the top end 281 are wettable sides 241 of the multilayer substrate 236.

On the bottom end 282, the following pads are on a side edge of the multilayer substrate 236: pad PWM for electrically connecting a pulse width modulation (PWM) signal that drives the pair of MOSFETs of the power die 206; pad CS for electrically connecting to a current sense signal; pad Vtemp for electrically connecting to a temperature sensing signal; pad EN for electrically connecting to an enable signal; pad 273 for electrically connecting to the input voltage VIN; pad 274 for electrically connecting to a ground reference; and pad Vcc for electrically connecting to a supply voltage. Also on the bottom end 282, the copper sink 235 is exposed through the power die package 242 to provide an electrical connection to the output voltage VOUT.

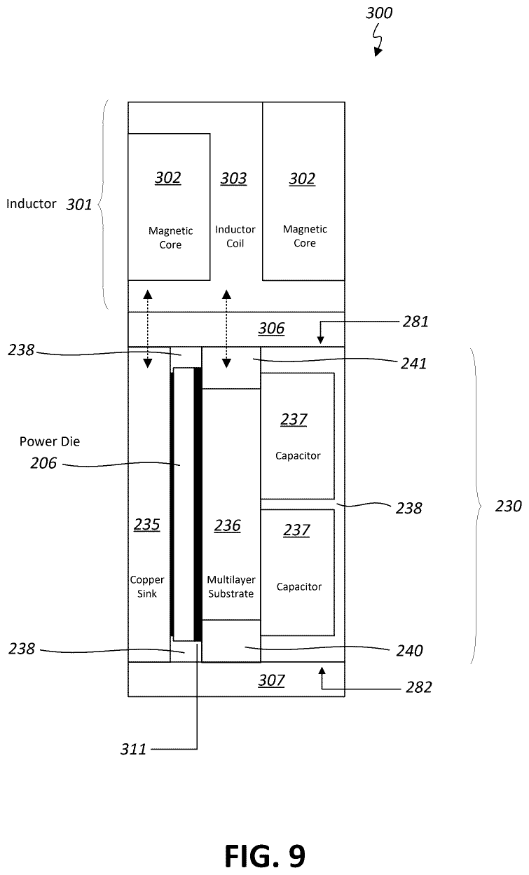

FIG. 9 shows a physical layout diagram of a power module 300 with a vertically-oriented power die 206, in accordance with an embodiment of the present invention. FIG. 9 shows a side edge of the power die 206. The bottom edge of the power die 206 faces toward a base substrate 307 (e.g., PCB).

The power module 300 is a single-phase power module. The power module 300 is the same as the power module 230, with the addition of a substrate 306 (e.g., interposer) on the top end 281 of the power module 230, an inductor 301 that is disposed on the substrate 306, and the base substrate 307 that is disposed on the bottom end 282 of the power module 230. Note that the power die 206 is disposed vertically relative to the plane of the base substrate 307. In one embodiment, the inductor 301 is the topmost component of the power module 300 and serves as an output inductor of the power converter implemented using the power module 300. Placing the inductor 301 to be the topmost component enhances the thermal performance of the power module 300.

The inductor 301 comprises an inductor coil 303 and a magnetic core 302. In one embodiment, the inductor 301 is a single-turn output inductor. Dashed arrows in FIG. 9 illustrate electrical connections of the inductor 301 to the multilayer substrate 236 and copper sink 235 through the substrate 306. In one embodiment, the copper sink 235 serves both as a heatsink and an interconnect for electrically connecting to the output voltage VOUT. More particularly, an end of the output inductor 301 is electrically connected to the output voltage VOUT, which is electrically connected to the copper sink 235. This allows efficient connection to the output voltage VOUT. The multilayer substrate 236 has wettable sides 240 and 241 for electrically connecting to nodes or interconnects in the multilayer substrate 236. Other components labeled in FIG. 9 correspond to those described with reference to FIG. 5.

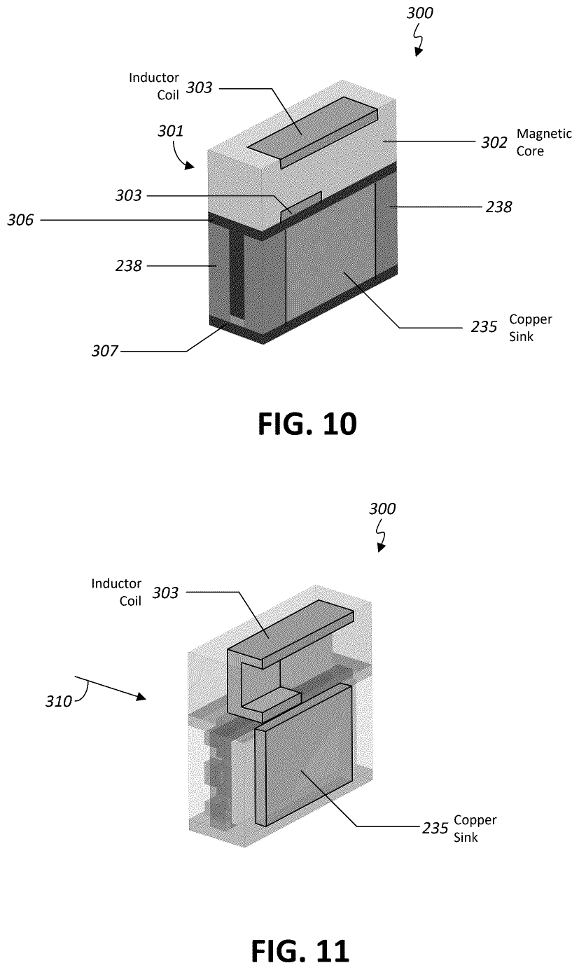

FIG. 10 shows a three-dimensional (3D) view of the power module 300, in accordance with an embodiment of the present invention. In one embodiment, a portion of the inductor coil 303 of the inductor 301 is exposed through the magnetic core 302. The copper sink 235 is exposed on an outermost surface of the power module 300 for improved heat dissipation. Other components labeled in FIG. 10 correspond to those described with reference to FIGS. 9 and 5.

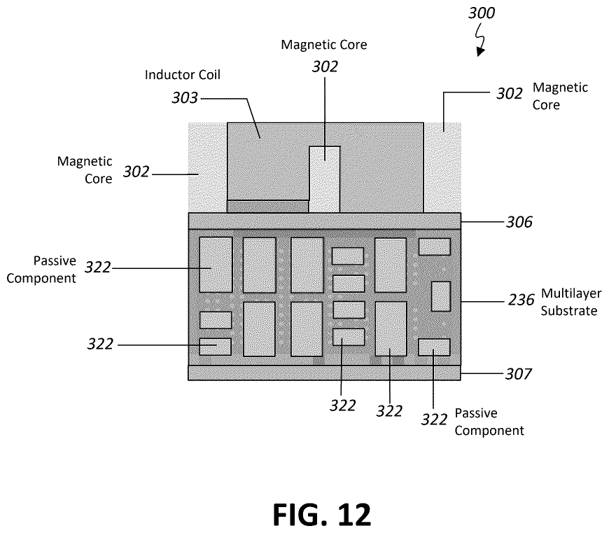

FIG. 11 shows a transparent 3D view of the power module 300, in accordance with an embodiment of the present invention. Labeled in FIG. 11 are the inductor coil 303 and the copper sink 235. A reference arrow 310 points to the second planar side of the multilayer substrate 236, which is shown in FIG. 12.

FIG. 12 shows the second planar side of the multilayer substrate 236, in accordance with an embodiment of the present invention. FIG. 12 represents a view in the direction of the arrow 310 shown in FIG. 11. The second planar side of the multilayer substrate 236 is a passive component side on which passive components 322 are mounted. Only some of the passive components are labeled in FIG. 12. Other components labeled in FIG. 12 correspond to those described with reference to FIGS. 9 and 5.

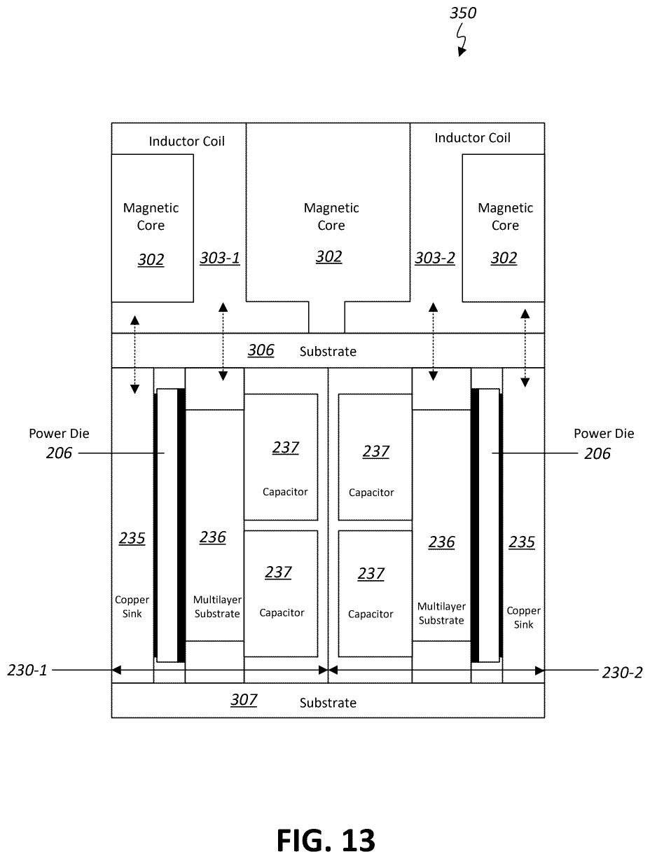

FIG. 13 shows a physical layout diagram of a power module 350 with a plurality of vertically-oriented power dies 206, in accordance with an embodiment of the present invention. FIG. 13 shows side edges of the power dies 206. The power module 350 is an embodiment in which two power modules 230 (i.e., 230-1, 230-2) and two inductor coils 303 (i.e., 303-1, 303-2) are utilized to generate two output voltage phases. Additional inductor coils 303 and power modules 230 may be incorporated to generate additional phases.

The inductor coils 303-1 and 303-2 share the same magnetic core 302, and form two output inductors, one for each phase. Two discrete inductors may also be used. The power module 230-1 is electrically connected to the inductor coil 303-1 to form a first regulator circuit that generates a first output voltage phase, and the power module 230-2 is electrically connected to the inductor coil 303-2 to form a second regulator circuit that generates a second output voltage phase. The output inductors formed by the inductor coils 303 and magnetic core 302 are disposed on the substrate 306, which is disposed on the top edges of the power dies 206. The bottom edges of the power dies 206 face toward the base substrate 307.

In the example of FIG. 13, planar sides of the copper sinks 235 face outward and are exposed on outer surfaces of the power module 350, whereas the passive component sides of the multilayer substrates 236 face inwards of the power module 350. This results in the capacitors 237 of the power module 230-1 facing the capacitors 237 of the power module 230-2. In each of the power modules 230, a corresponding power die 206 is disposed upright between corresponding copper sink 235 and multilayer substrate 236.

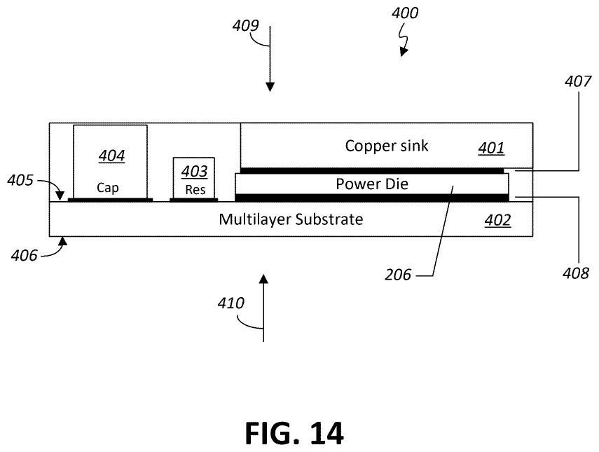

FIG. 14 shows a physical layout diagram of a power module 400 with a vertically-oriented power die 206, in accordance with an embodiment of the present invention. The power module 400 is depicted horizontally for illustration purposes. FIG. 14 shows a side edge of the power die 206. In the power module 400, a copper sink 401, vertically-oriented power die 206, and passive components are on a planar side 405 of a multilayer substrate 402. As will be more apparent below, output inductors may be disposed between adjacent power modules 400.

In the example of FIG. 14, a capacitor 404 (e.g., size 0402 capacitor), a resistor 403 (e.g., a size 0201 resistor), and other passive components are mounted on the planar side 405. The multilayer substrate 402 may have several layers for incorporating different interconnect structures, passive components, etc. The multilayer substrate 402 has a planar side 406. Output inductors may be disposed between planar sides 406 of multilayer substrates 402 of corresponding adjacent power modules 400.

A copper sink 401 serves as a heatsink and is attached to the first planar side of the power die 206 by a thermal interface material 407 (e.g., thermal glue). The second planar side of the power die 206 is attached to the planar side 405 of the multilayer substrate 402 by contact points 408 (e.g., solder bumps). Empty regions in the power module 400 may be filled by molding compound. Also shown in FIG. 14 are a reference arrow 409 that points toward the first planar side of the power die 206 and the planar side 405 of the multilayer substrate 402, and a reference arrow 410 that points toward the second planar side of the power die 206 and the planar side 406 of the multilayer substrate 402.

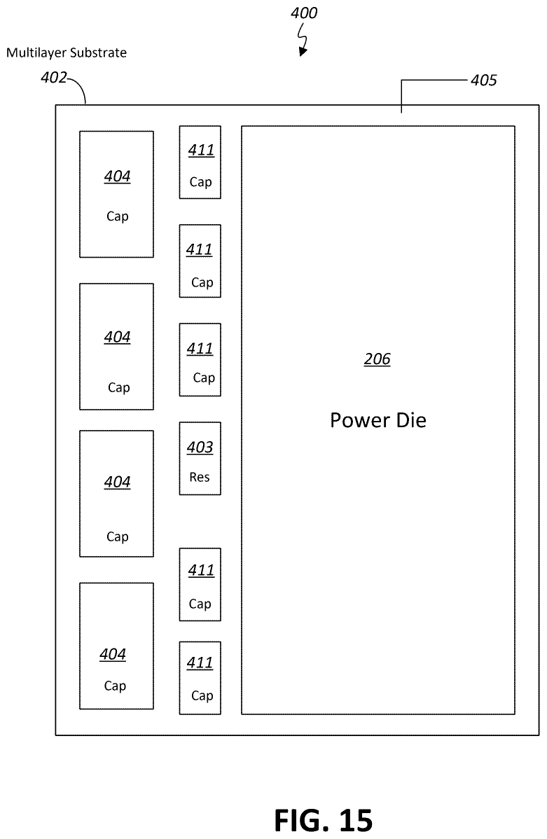

FIG. 15 shows the planar side 405 of the multilayer substrate 402, in accordance with an embodiment of the present invention. FIG. 15 represents a view in the direction of the reference arrow 409 shown in FIG. 14, with the copper sink 401 omitted. As illustrated in FIG. 15, the power die 206 and passive components are mounted on the planar side 405 of the multilayer substrate 402. The planar side 406 (not shown in FIG. 15) of the multilayer substrate 402 faces toward the output inductor of the power module 400. In the example of FIG. 15, the passive components include capacitors 404 (e.g., size 0402 input capacitors), capacitors 411 (e.g., size 0201 capacitors), and resistor 403 (e.g., size 0201 resistor).

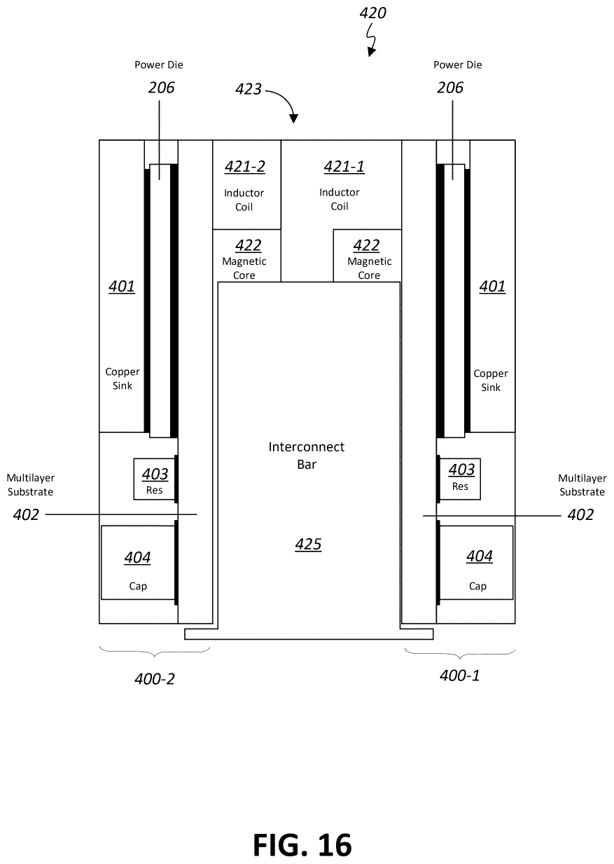

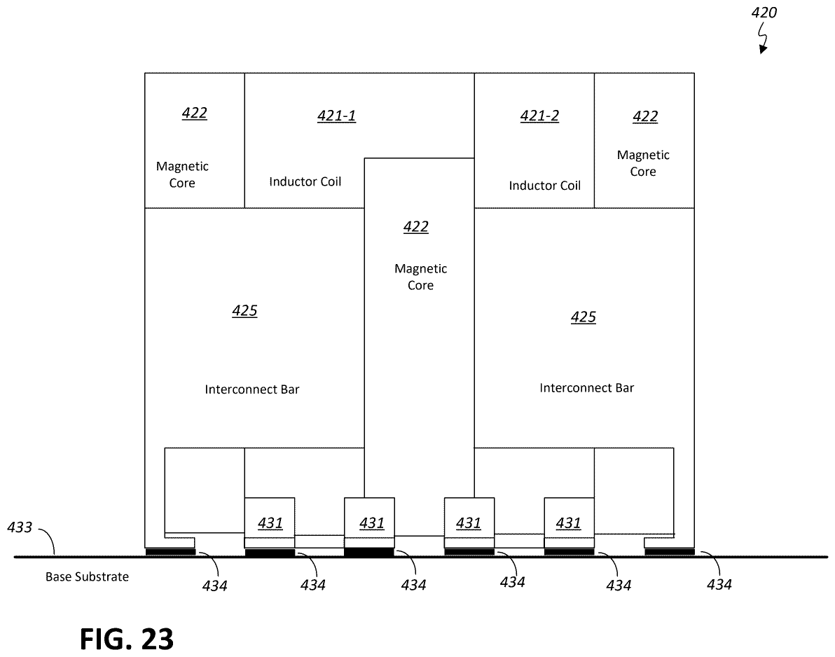

FIG. 16 shows a physical layout diagram of a power module 420 with a plurality of vertically-oriented power dies 206, in accordance with an embodiment of the present invention. FIG. 16 shows side edges of the power dies 206. The bottom edges of the power dies 206 face toward a base substrate (not shown in FIG. 16; see FIG. 23, base substrate 433). As before, the power dies 206 are vertically-oriented relative to the base substrate.

The power module 420 includes two inductor coils 421 (i.e., 421-1, 421-2) and two power modules 400 (i.e., 400-1, 400-2) to generate two output voltage phases. Additional inductor coils 421 and power modules 400 may be incorporated to generate additional phases.

The inductor coils 421-1 and 421-2 share the same magnetic core 422, and form two output inductors, one for each phase. The power module 400-1 is electrically connected to the inductor coil 421-1 by way of a corresponding multilayer substrate 402 to form a first regulator circuit that generates a first output voltage phase, and the power module 400-2 is electrically connected to the inductor coil 421-2 by way of a corresponding multilayer substate 402 to form a second regulator circuit that generates a second output voltage phase. The inductors 423 formed by the inductor coils 421 and magnetic core 422 are between the multilayer substrates 402 of the power modules 400.

In the power module 420, the inductors 423 are exposed on the top outer surface of the power module 420 for enhanced thermal performance. For similar reason, the copper sinks 401 are exposed on side outer surfaces of the power module 420. Interconnect bars provide electrical connection to power, such as input voltage and power ground. In the example of FIG. 16, an interconnect bar 425 is attached to the magnetic core 422.

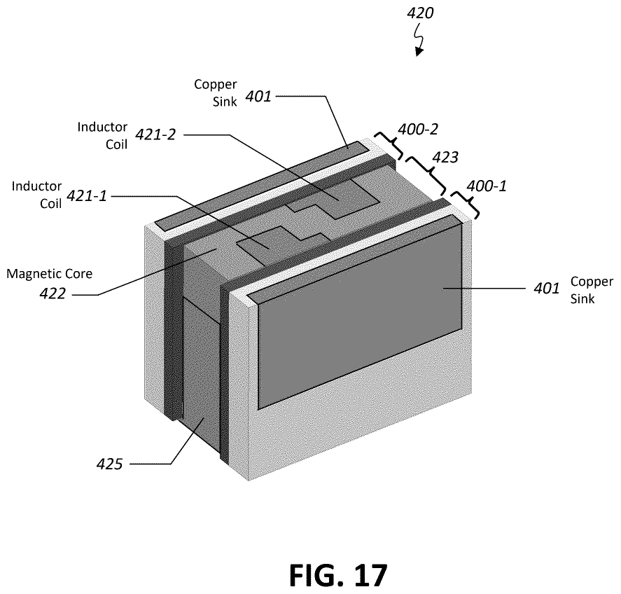

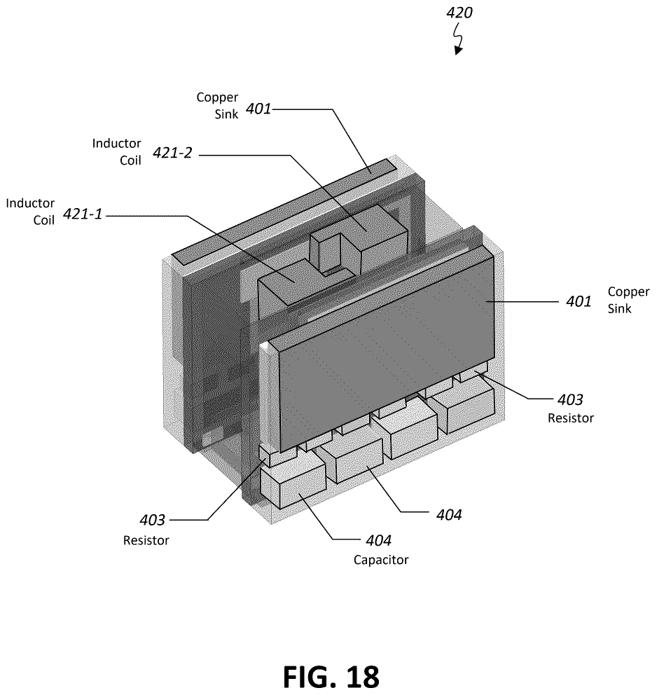

FIGS. 17 and 18 show a 3D view and a transparent 3D view, respectively, of the power module 420, in accordance with an embodiment of the present invention. The labeled components in FIGS. 17 and 18 correspond to those described with reference to FIGS. 14 and 16.

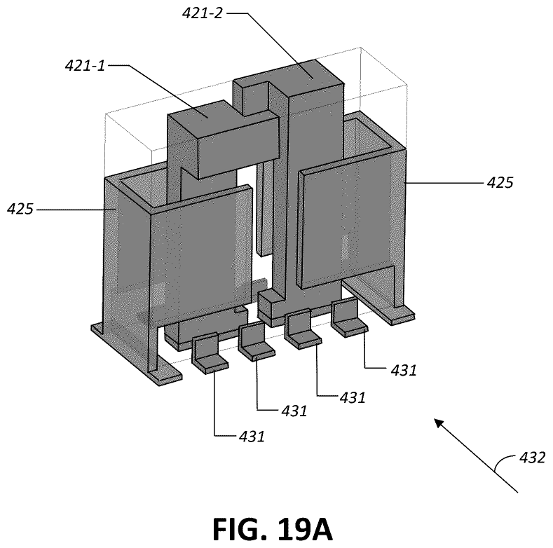

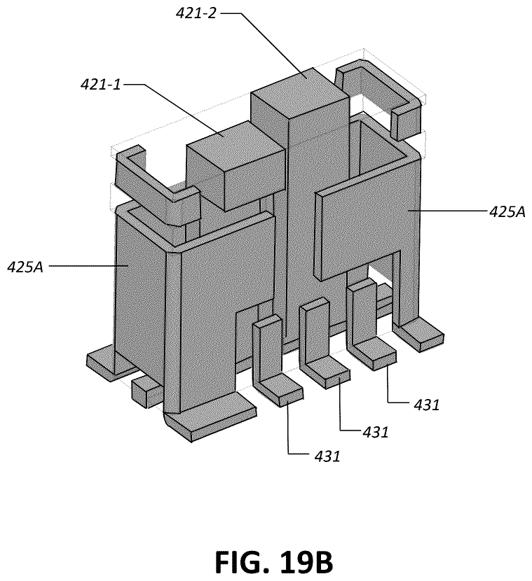

FIG. 19A shows a transparent 3D view of the power module 420, in accordance with an embodiment of the present invention. FIG. 19A only shows the inductor coils 421-1 and 421-2, interconnect bars 425, and pads 431. In one embodiment, the pads 431 are L-shaped. The pads 431 provide contact points to a base substrate (not shown) that supports the power module 420. The pads 431 are electrically connected to corresponding nodes of the power module 420. The electrical connections may be made through substrates, interconnect bars, etc. of the power module 420. A reference arrow 432 points toward a front of the power module 420.

FIG. 19B shows a transparent 3D view of the power module 420, in accordance with an embodiment of the present invention. FIG. 19B only shows the inductor coils 421-1 and 421-2, interconnect bars 425A, and pads 431. An interconnect bar 425A is an embodiment of the interconnect bar 425 of FIG. 19A, with higher notching to accommodate taller pads 431.

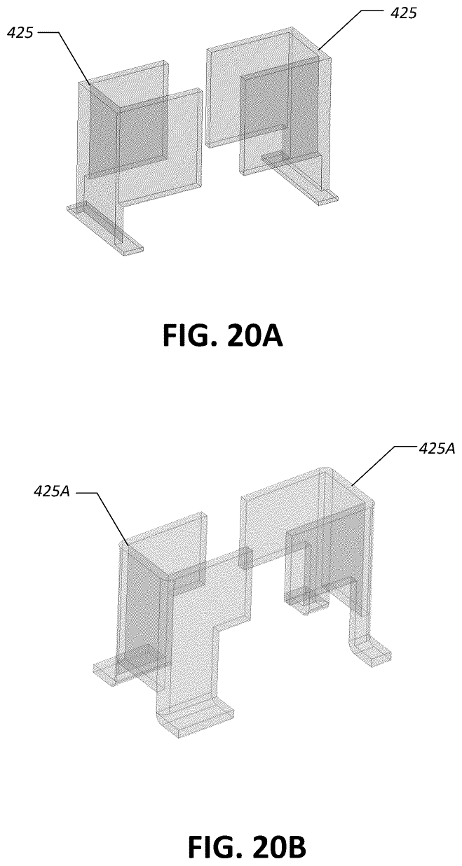

FIG. 20A shows a transparent 3D view of the interconnect bars 425 (see FIG. 19A), in accordance with an embodiment of the present invention.

FIG. 20B shows a transparent 3D view of the interconnect bars 425A (see FIG. 19B), in accordance with an embodiment of the present invention.

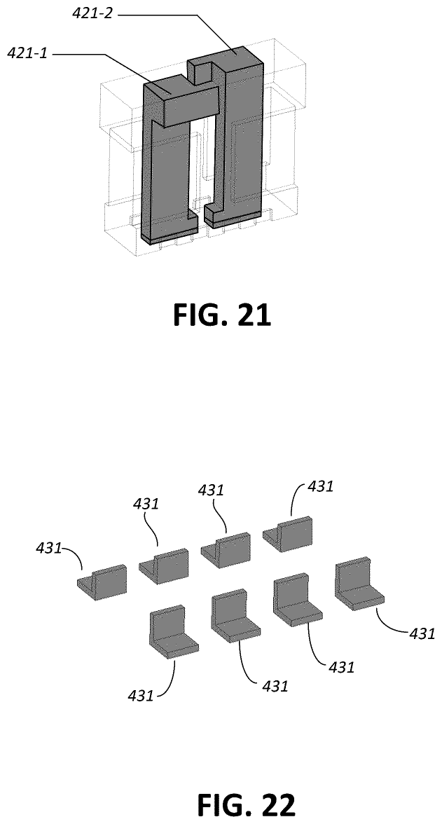

FIG. 21 shows a 3D view of the inductor coils 421-1 and 421-2, in accordance with an embodiment of the present invention.

FIG. 22 shows a 3D view of pads 431, in accordance with an embodiment of the present invention.

FIG. 23 shows a front of the power module 420, in accordance with an embodiment of the present invention. FIG. 23 represents a view in the direction of the reference arrow 432 shown in FIG. 19A. Shown in FIG. 23 are the inductor coils 421-1 and 421-2, magnetic core 422, interconnect bars 425, and pads 431. Schematically illustrated in FIG. 23 is the base substrate 433 that supports the power module 420. The pads 431 are electrically connected to the base substrate 433 by contact points 434 (e.g., solder bumps). Note that the power dies 206 (not shown in FIG. 23) are disposed vertically relative to the plane of the base substrate 433.

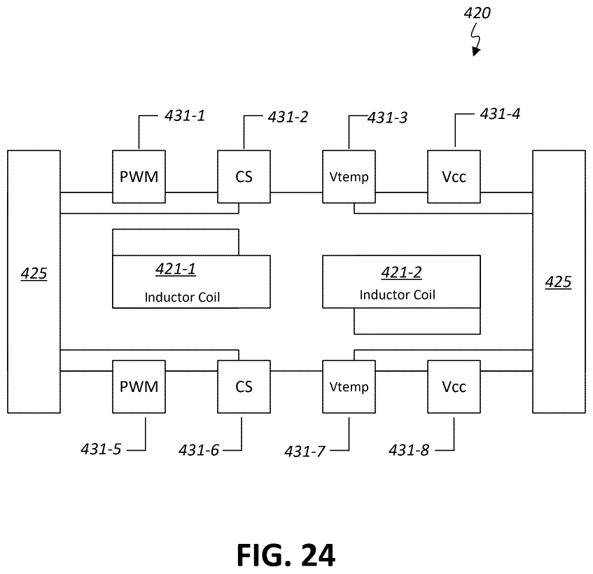

FIG. 24 shows a bottom end of the power module 420, in accordance with an embodiment of the present invention. Shown in FIG. 24 are the inductor coil 421-1 of the power module 400-1, inductor coil 421-2 of the power module 400-2, interconnect bars 425, and pads 431 (i.e., 431-1, 431-2, 431-3 etc.). In the example of FIG. 24, the pads 431-1 to 431-4 are electrically connected to nodes of the power module 400-1, whereas the pads 431-5 to 431-8 are electrically connected to nodes of the power module 400-2. The pad 431-1 is electrically connected to a PWM signal, pad 431-2 is elected connected to a chip select signal, pad 431-3 is electrically connected to a temperature signal, and pad 431-4 is electrically connected to supply voltage. The pads 431-5 to 431-8 of the power module 400-2 are similarly connected.

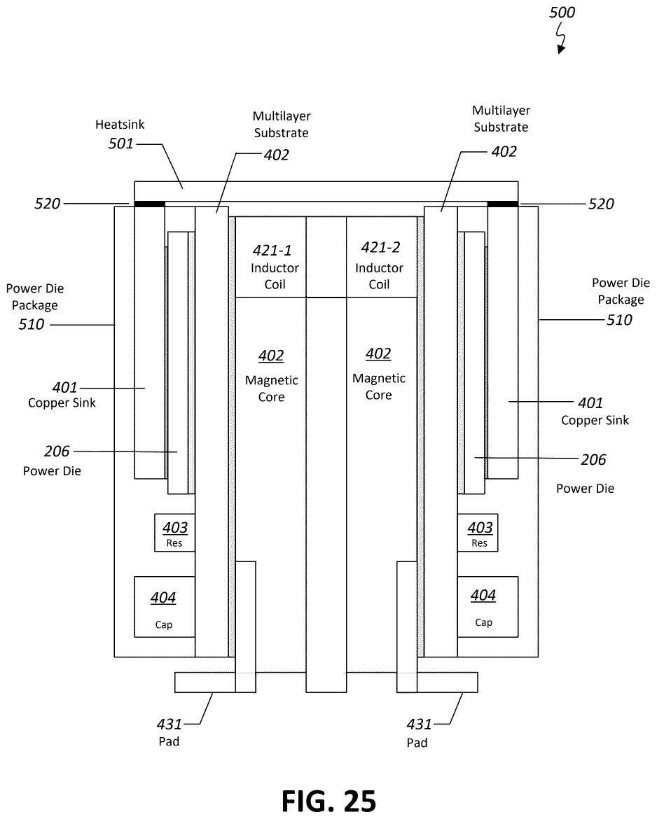

FIG. 25 shows a physical layout diagram of a power module 500 with a plurality of vertically-oriented power dies 206, in accordance with an embodiment of the present invention. FIG. 25 shows side edges of the power dies 206. The bottom edges of the power dies 206 face toward a base substrate (not shown in FIG. 25), to which the pads 431 are attached.

The power module 500 has two vertically-oriented power dies 206 to generate two output voltage phases. The power module 500 is an embodiment of the power module 420 (shown in FIG. 16) with the addition of a heatsink 501 on the top end.

In one embodiment, a power die package 510 includes a copper sink 401, vertically-oriented power die 206, and passive components, such as one or more capacitors 404 and one or more resistors 403. Empty regions in the power die package 510 may be filled with molding compound. The power die 206 and passive components are electrically connected to a multilayer substrate 402 as in the power module 420. Also shown in FIG. 25 are the inductors 421-1 and 421-2, magnetic core 402, and pads 431.

Each of the copper sinks 401 has a soldering surface that is exposed through the power die package 510 at the top end of the power module 500. The heatsink 501 may be attached to the copper sinks 401 by an interface material 520, such as a thermal glue or solder. Heat from the copper sinks 401 are thus conducted to the heatsink 501. The heatsink 501 enhances the heat dissipation surface of the power module 500 for enhanced thermal performance. Optionally, the heatsink 501 may also be attached to the output inductors by thermal interface material 520 for enhanced thermal and mechanical performance.

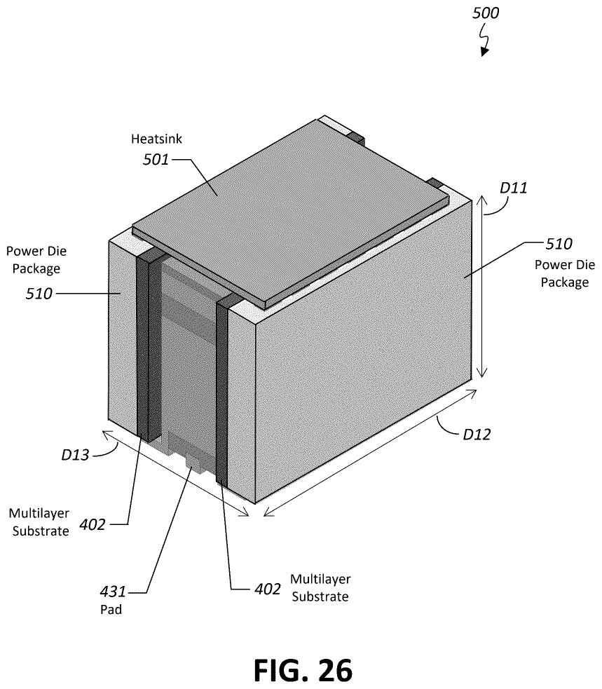

FIG. 26 shows a 3D view of the power module 500, in accordance with an embodiment of the present invention. In one embodiment, the power module 500 has a dimension D11 of 5 mm, dimension D12 of 6.2 mm, and a dimension D13 of 4.2 mm. The labeled components of FIG. 26 correspond to those described with reference to FIGS. 16 and 25.

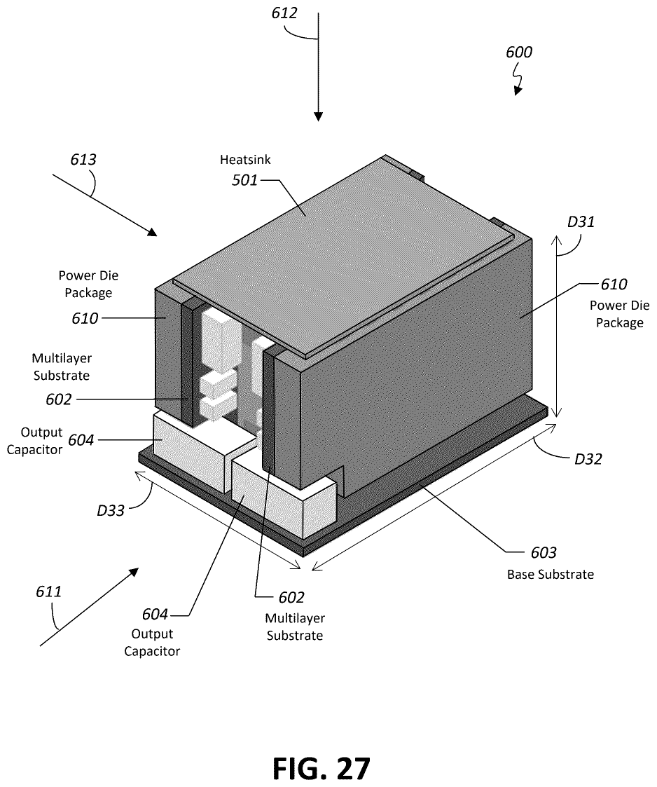

FIG. 27 shows a 3D view of a power module 600 with vertically-oriented power dies 206, in accordance with an embodiment of the present invention. The power module 600 is an embodiment of the power module 500 in which the multilayer substrate 402 and power die package 510 are trimmed to make room for output capacitors 604. The multilayer substrate 402 and the power die package 510 are relabeled as “602” and “610”, respectively, for clarity of illustration.

In the example of FIG. 27, the output capacitors 604 and the power die packages 610 are mounted on a base substrate 603 (e.g., PCB). It is to be noted that the power dies 206 in the power die packages 610 are disposed vertically relative to the base substrate 603. The multilayer substrates 602 and power die packages 610 have notches to accommodate the output capacitors 604 underneath. In one embodiment, the power module 600 has a dimension D31 of 4.75 mm, dimension D32 of 7.35 mm, and a dimension D33 of 4.95 mm. Also shown in FIG. 27 is the heatsink 501, which is attached to the copper sinks 401 (not shown in FIG. 27) in the power die packages 610. Reference arrows 611, 612, and 613 point toward a front, top, and side, respectively, of the power module 600

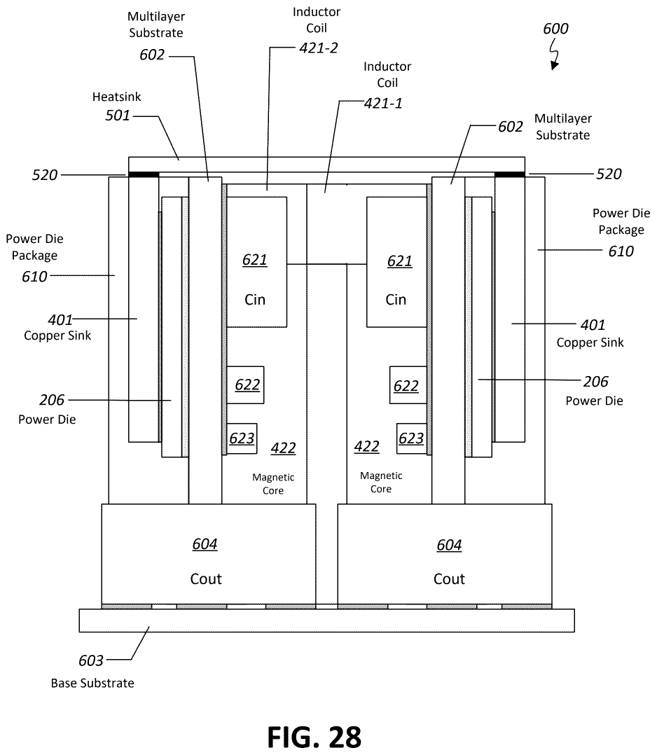

FIG. 28 shows a physical layout diagram of the power module 600, in accordance with an embodiment of the present invention. FIG. 28 shows side edges of the power dies 206, and is viewed in the direction of the reference arrow 611 shown in FIG. 27. The power module 600 includes two vertically-oriented power dies 206 to generate two output voltage phases. The bottom edges of the power dies 206 face toward the base substrate 603.

Each power die package 610 includes a copper sink 401 and vertically-oriented power die 206. Empty regions in the power die package 610 may be filled with molding compound. The power die 206 is electrically connected to the multilayer substrate 602. In the example of FIG. 28, the power die 206 is mounted on a first planar side of the multilayer substrate 602, and passive components are mounted on a second planar side of the multilayer substrate 602. Such passive components include input capacitors 621, capacitors 622, and resistors 623. Output inductors formed by the inductor coil 421-1, inductor coil 421-2, and magnetic core 402 are disposed between the multilayer substrates 602.

Each of the copper sinks 401 has a soldering surface that is exposed through the power die package 620 at the top end of the power module 600. The heatsink 501 may be attached to the copper sinks 401 by an interface material 520 (e.g., thermal glue, solder). Optionally, the heatsink 501 may also be attached to the output inductors by thermal interface material 520 for enhanced thermal and mechanical performance.

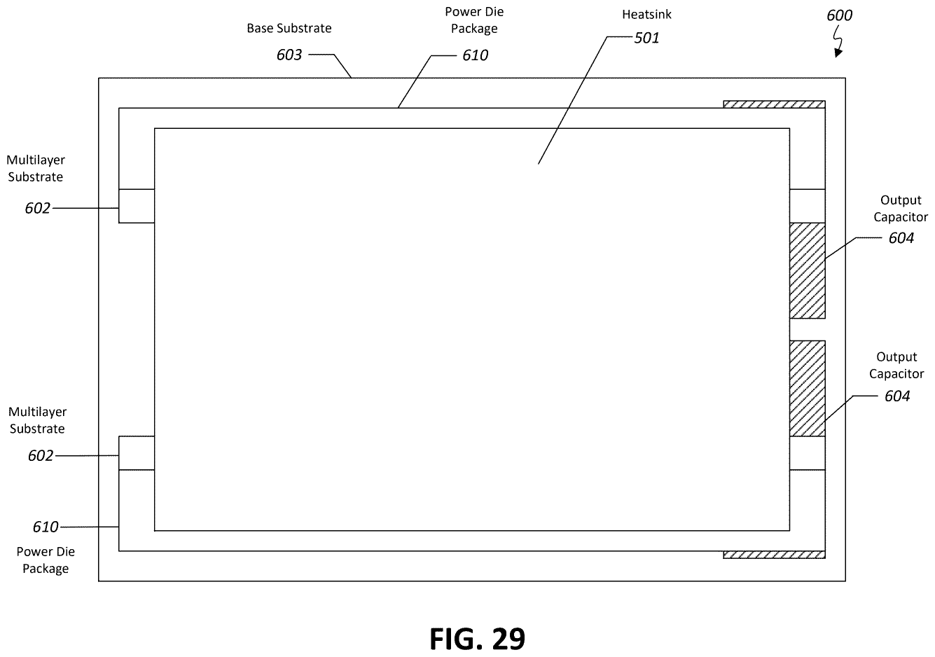

FIG. 29 shows a top end of the power module 600, in accordance with an embodiment of the present invention. FIG. 29 represents a view in the direction of the reference arrow 612 shown in FIG. 27. The output capacitors 604 are depicted with hashed lines for clarity. Also shown in FIG. 29 are the heatsink 501, multilayer substrates 602, power die packages 610, and base substrate 603.

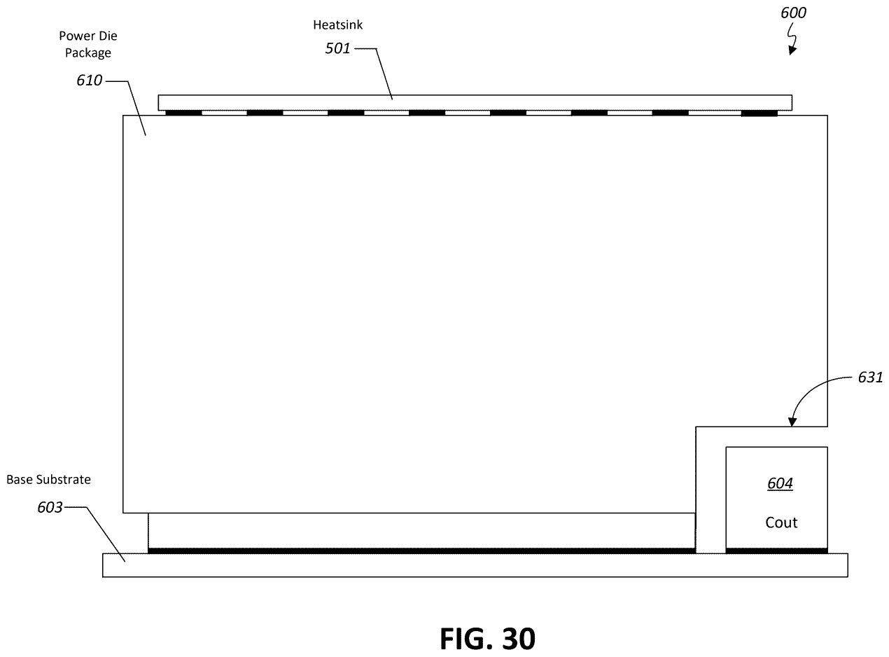

FIG. 30 shows a side of the power module 600, in accordance with an embodiment of the present invention. FIG. 30 represents a view in the direction of the reference arrow 613 shown in FIG. 27. Shown in FIG. 30 are the heatsink 501, base substrate 603, power die package 610, and output capacitor 604. The output capacitors 604 are under a notch 631 of the power die packages 610 and multilayer substrates 602 (not shown in FIG. 30).

As used herein, the term “inductor structure” refers to an arrangement that includes at least one inductor coil and at least one magnetic core, and may further include electrical connection features such as pads, wettable sides, interconnect bars, solder joints, or substrates that support electrical or mechanical connection to a power module, a base substrate, or other nodes.

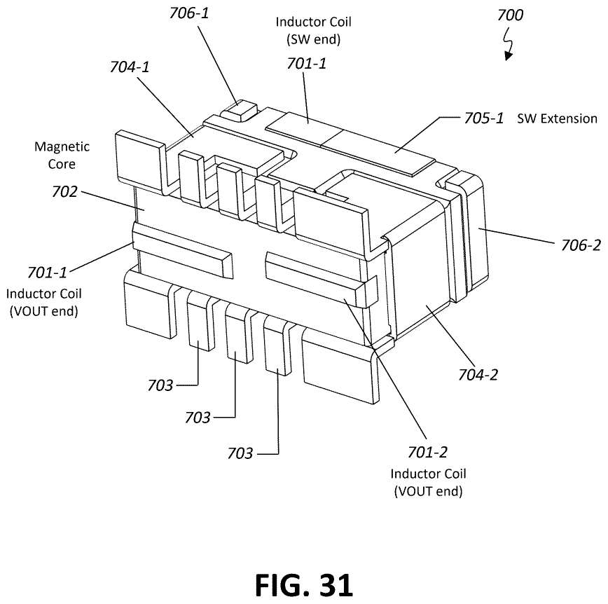

An example of a previously introduced inductor structure comprises the inductor coils 421-1 and 421-2 disposed on a shared magnetic core 422, together with electrical connection features including pads 431 and interconnect bars 425 or 425A. Additional inductor structures are now introduced, beginning with FIG. 31. These additional inductor structures may be used in place of or in addition to previously disclosed inductor structures, and may be incorporated into the corresponding power modules 400, 420, 500, or 600, as well as other power modules that utilize vertically-oriented power dies. For example, an inductor structure may be incorporated in a power module that is disposed on a motherboard, with the power module incorporating two other power modules that are adjacent. The inductor structure may be disposed between the two other power modules, each having a vertically-oriented power die, with pads of the inductor structure being attached to a base substrate. In such configurations, a power module may electrically connect to the inductor structure by way of a multilayer substrate.

For clarity of illustration, not all components shown in the figures are labeled, and not all illustrated components are described in detail. Certain elements may be depicted schematically or without reference numbers. Such elements are shown to provide context and are not intended to limit the scope of the present disclosure. Features that correspond to previously described components may be understood to have a similar structure or function unless expressly stated otherwise.

Referring now to FIG. 31, there is shown a 3D view of an inductor structure 700, in accordance with an embodiment of the present invention. The inductor structure 700 is a two-phase inductor structure in that it includes two output inductors, one for each phase, disposed around a same magnetic core. In one embodiment, each of the output inductors is a single-turn inductor. In the example of FIG. 31, the first output inductor comprises an inductor coil 701-1 and a magnetic core 702, and the second output inductor comprises an inductor coil 701-2 and the magnetic core 702. Generally, inductor coils disclosed herein my comprise a material that is commonly-used for inductor coils, including copper. Similarly, a magnetic core may comprise a magnetic material commonly-used in magnetic cores including a magnetic alloy, such as sendust. Metal and electrical connection components may comprise copper or aluminum, and tin for solder connections, for example.

In one embodiment, the inductor structure 700 has a generally block-like outer profile with a bottom side, a top side, a pair of wide sides, and a pair of narrow sides. As its name indicates, a narrow side is narrower than a wide side. The block-like profile may allow placement of copper or other metal structures on multiple sides to improve heat dissipation. For example, interconnect bars 704 (i.e., 704-1 and 704-2), which may comprise copper, are positioned on the narrow sides and may extend onto the wide sides and provide pads on the bottom side. A copper heatsink may be attached to the top side, for example as in the inductor structure of the power module 500 (see FIGS. 25 and 26).

The inductor structure 700 is depicted in FIG. 31 with its bottom side facing toward the viewer. The end of an inductor coil 701 (i.e., 701-1 or 701-2) that is exposed on the bottom side of the inductor structure 700 is also referred to herein as the “VOUT end”, as it is electrically connected to the output voltage node of the corresponding phase. The opposing end of the inductor coil 701 is referred to herein as the “SW end”, as it is electrically connected to the switch node formed by a pair of MOSFETs in a corresponding vertically-oriented power die.

The SW end of each inductor coil 701 is exposed on a corresponding wide side of the inductor structure 700. In one embodiment, an SW extension is electrically connected to the SW end of an inductor coil 701. The SW extension comprises a conductive member that extends from the SW end along the corresponding wide side of the inductor structure 700. The SW extension provides an enlarged contact region for electrically connecting the inductor coil 701 to the switch node of the corresponding vertically-oriented power die.

The SW extension may have a greater surface area than the SW end of the inductor coil 701, which facilitates electrical connection, reduces conduction resistance, and improves heat dissipation. In certain embodiments, the SW extension is formed as a separate piece mechanically and electrically coupled to the SW end. In other embodiments, the SW extension and the SW end are formed as a single integral piece.

The inductor structure 700 further includes pads 703 and interconnect bars 704 (i.e., 704-1 and 704-2), which correspond to previously introduced pads 431 and interconnect bars 425/425A (see, e.g., FIGS. 19A and 19B). In one embodiment, the interconnect bar 704-1 is electrically connected to the input voltage (VIN) node, and the interconnect bar 704-2 is electrically connected to ground (GND). The pads 703 are electrically connected to corresponding nodes of a power module that incorporates the inductor structure 700. The inductor structure 700 further includes metal portions 706 (i.e., 706-1 and 706-2), which in one embodiment are pads for signal connections.

In one embodiment, the VOUT ends of the inductor coils 701 are laterally offset from one another along a length of the bottom side. Each VOUT end has a generally rectangular shape with a corresponding centerline, and the centerlines of the two VOUT ends are parallel but spaced apart, such that the VOUT ends are not collinear and do not overlap. This intentional misalignment results in a more uniform magnetic cross-sectional area, reduces magnetic coupling between the phases, and facilitates achieving high power density and high efficiency.

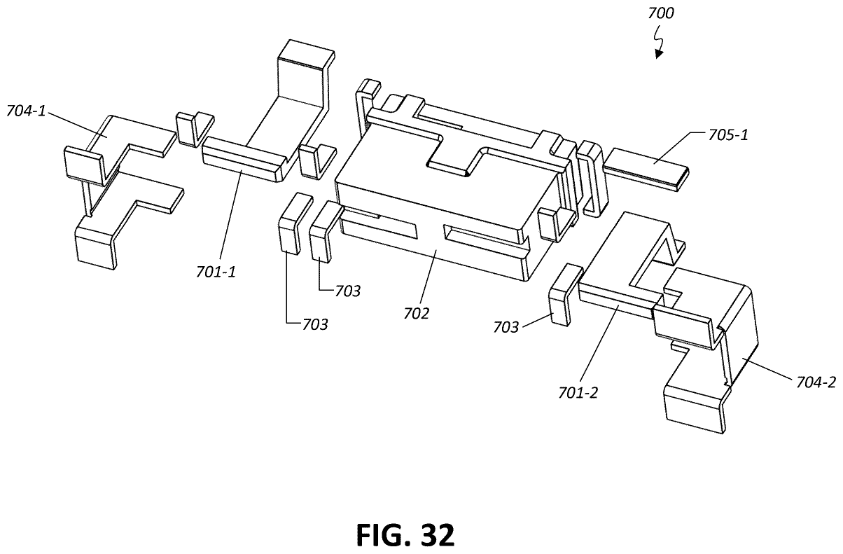

FIG. 32 shows an exploded view of the inductor structure 700, in accordance with an embodiment of the present invention. The exploded view is presented for illustrative purposes to show relative positions of various components of the inductor structure 700. The depiction is schematic in nature and is not intended to represent precise physical dimensions, proportions, or assembly sequences. Certain features may be simplified, omitted, or shown without reference numbers for clarity of illustration. Components that correspond to previously described elements may be understood to operate in a similar manner unless expressly stated otherwise. In FIG. 32, various components of the inductor structure 700, including the inductor coils 701, the magnetic core 702, pads 703, SW extension 705-1, and interconnect bars 704, are illustrated in an exploded manner to show their relative positions.

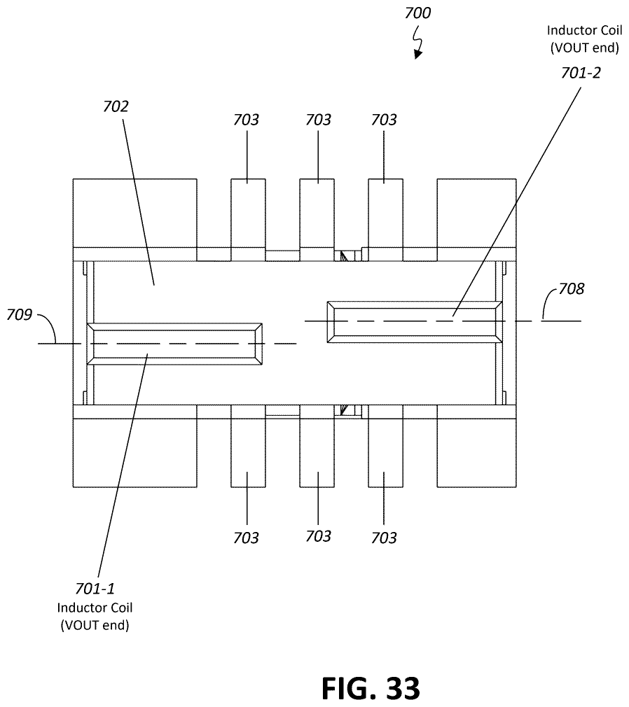

FIG. 33 shows a bottom view of the inductor structure 700, in accordance with an embodiment of the present invention. Labeled in FIG. 33 are the pads 703, the magnetic core 702, and the VOUT ends of the inductor coils 701. Each VOUT end has a generally rectangular shape with a corresponding centerline 708 or 709. The centerlines 708 and 709 are parallel but spaced apart, indicating that the VOUT ends are laterally offset from one another. The pads 703 are along opposing wide sides of the outer profile of the inductor structure 700. When the inductor structure is disposed between two adjacent power modules, the pads 703 on one wide side are electrically connected to nodes of the power module adjacent to that side, and the pads 703 on the other wide side are electrically connected to nodes of the power module adjacent to the other side.

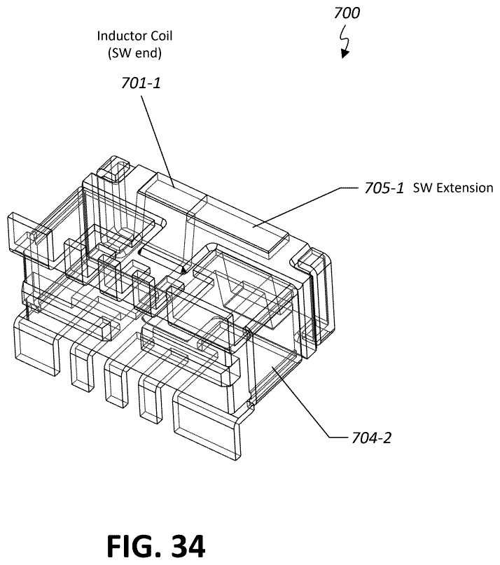

FIG. 34 shows a wireframe view of the inductor structure 700, in accordance with an embodiment of the present invention. The wireframe representation is provided to illustrate the overall geometry of the components of the inductor structure 700 without surface shading. Labeled in FIG. 34 for reference purposes are the SW end of inductor coil 701-1, the SW extension 705-1, and the interconnect bar 704-2.

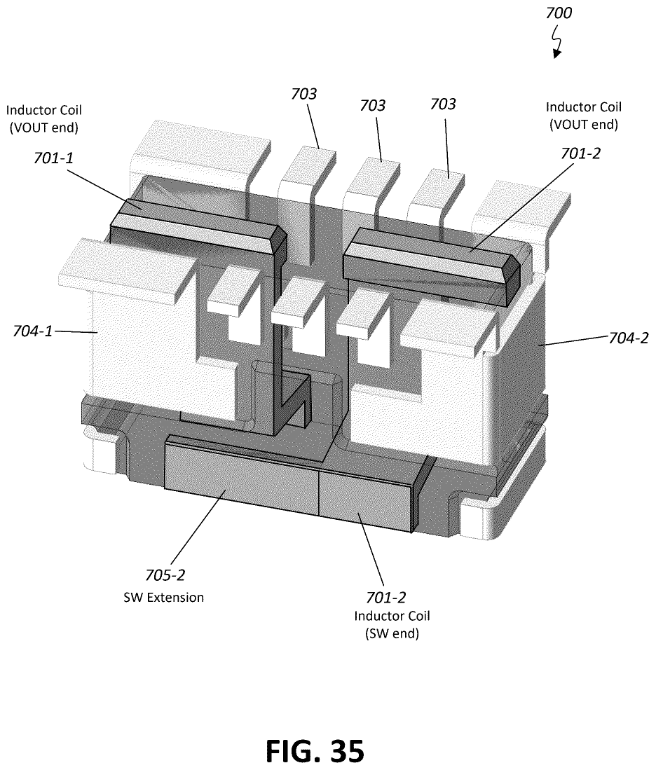

FIG. 35 shows a transparent 3D view of the inductor structure 700, in accordance with an embodiment of the present invention. The transparent depiction provides an alternate perspective for viewing the components within the inductor structure 700. Labeled in FIG. 35 for reference are the inductor coils 701-1 and 701-2, pads 703, interconnect bars 704-1 and 704-2, and the SW extension 705-2.

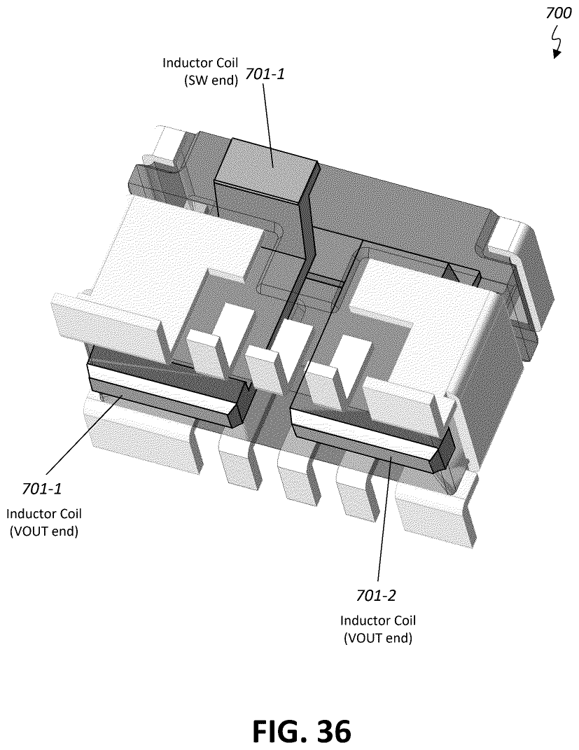

FIG. 36 shows another transparent 3D view of the inductor structure 700, in accordance with an embodiment of the present invention. Labeled in FIG. 36 for reference are the VOUT and SW ends of inductor coil 701-1, and the VOUT end of the inductor coil 701-2. In this embodiment, the SW end of inductor coil 701-1 does not include an SW extension, illustrating that the configuration of the SW end may be varied or adjusted depending on design requirements. The geometry of the SW end, including whether an SW extension is present and the shape or size of such an extension, may be selected to achieve desired electrical, magnetic, or thermal characteristics of the inductor structure. Other aspects of the inductor structure in FIG. 36 remain as previously described.

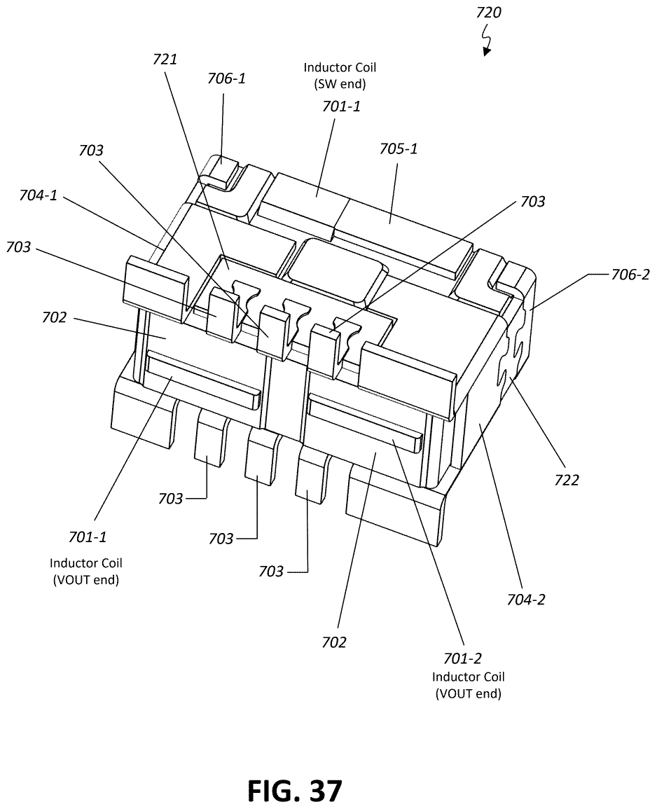

FIG. 37 shows a 3D view of an inductor structure 720, in accordance with an embodiment of the present invention. The inductor structure 720 is similar to the inductor structure 700 except that it further includes auxiliary support members positioned between metal components. In the example of FIG. 37, the auxiliary support members include support members 721 and 722, which may be formed from a non-electrically conductive material such as phenolic plastic. Generally, auxiliary support members allow pads to adhere more firmly to the magnetic core and to achieve better coplanarity. Furthermore, auxiliary support members may provide mechanical stability or alignment.

Support member 721 is positioned along a wide side of the inductor structure 720 and occupies a region between interconnect bars 704 and pads 703. Support member 722 is positioned along a narrow side of the inductor structure 720 and occupies a region between an interconnect bar 704 and a metal portion 706. Other aspects of the inductor structure 720 are as previously described with reference to the inductor structure 700.

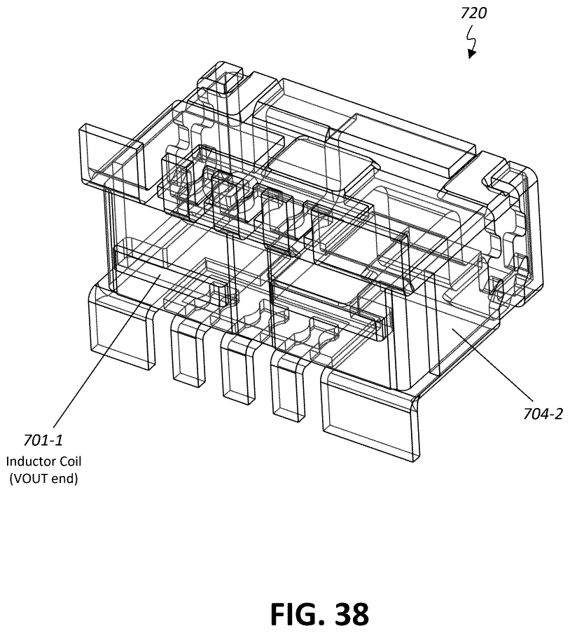

FIG. 38 shows a wireframe view of the inductor structure 720, in accordance with an embodiment of the present invention. The wireframe depiction provides an alternate perspective for viewing the outline of the components of the inductor structure 720. Labeled in FIG. 38 for reference are the VOUT end of inductor coil 701-1 and the interconnect bar 704-2.

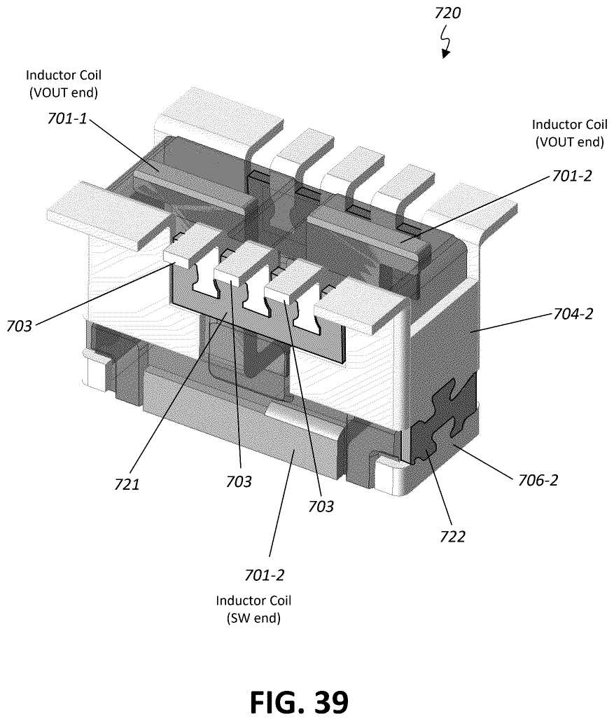

FIG. 39 shows a transparent 3D view of the inductor structure 720, in accordance with an embodiment of the present invention. The transparent depiction provides another perspective for viewing the arrangement of components within the inductor structure 720. The components labeled in FIG. 39 correspond to those previously described.

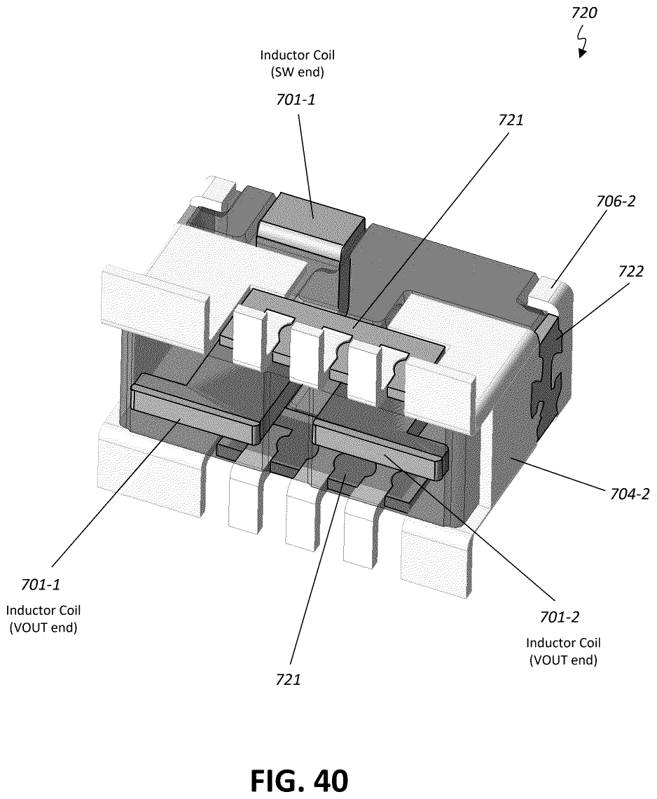

FIG. 40 shows another transparent 3D view of the inductor structure 720, in accordance with an embodiment of the present invention. In this embodiment, the SW end of inductor coil 701-1 does not include an SW extension, illustrating that the geometry of the SW end may be varied among different embodiments. The components labeled in FIG. 40 correspond to those previously described, except for the absence of the SW extension 705-1.

The geometry and arrangement of the components of inductor structures disclosed herein may be varied to suit the requirements of different applications. For example, the configuration of the VOUT ends, the placement of the SW ends, the presence or absence of SW extensions, and the number of inductor coils may be adjusted depending on the intended application. The following figures illustrate several such variations, each of which may be used in place of or in addition to those previously described.

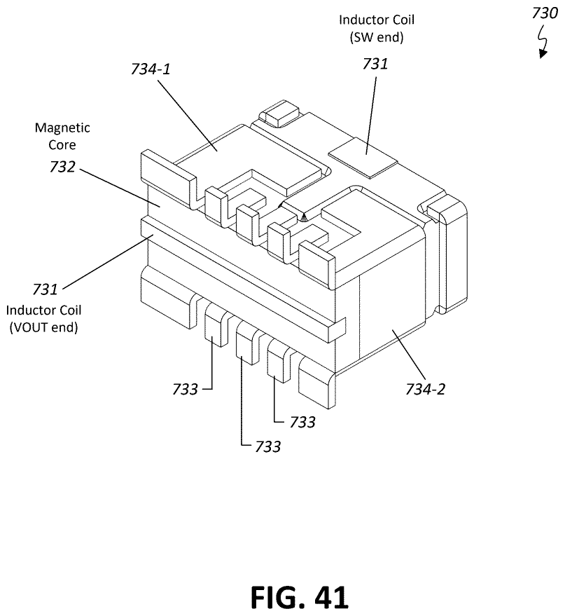

FIG. 41 shows a 3D view of an inductor structure 730, in accordance with an embodiment of the present invention. The inductor structure 730 is a single-phase inductor structure in that it has a single output inductor. In the example of FIG. 41, the output inductor comprises an inductor coil 731 that is wound around a magnetic core 732 one turn.

In one embodiment, the inductor structure 730 has a generally block-like outer profile with a bottom side, a top side, a pair of wide sides, and a pair of narrow sides. Interconnect bars 734 (i.e., 734-1 and 734-2), which may comprise copper, are positioned on the narrow sides and may extend onto the wide sides and provide pads on the bottom side. A copper heatsink may be attached to the top side.

The inductor structure 730 is depicted in FIG. 41 with its bottom side facing toward the viewer. The VOUT end of the inductor coil 731 is exposed on the bottom side of the inductor structure 730 and is electrically connected to the output voltage node. The VOUT end of the inductor coil 731 may be disposed across the exposed surface of the magnetic core 732. The SW end of the inductor coil 731, which is electrically connected to the switch node formed by the pair of MOSFETs of a vertically-oriented power die, is exposed on one of the wide sides of the inductor structure 730.

The inductor structure 730 further includes pads 733 and interconnect bars 734 (i.e., 734-1 and 734-2). In one embodiment, the interconnect bar 734-1 is electrically connected to the input voltage node, and the interconnect bar 734-2 is electrically connected to ground. The pads 733 are electrically connected to corresponding nodes of a power module that incorporates the inductor structure 730. In some embodiments, the inductor structure 730 may further include auxiliary support members similar to support members 721 and 722, positioned between adjacent metal components.

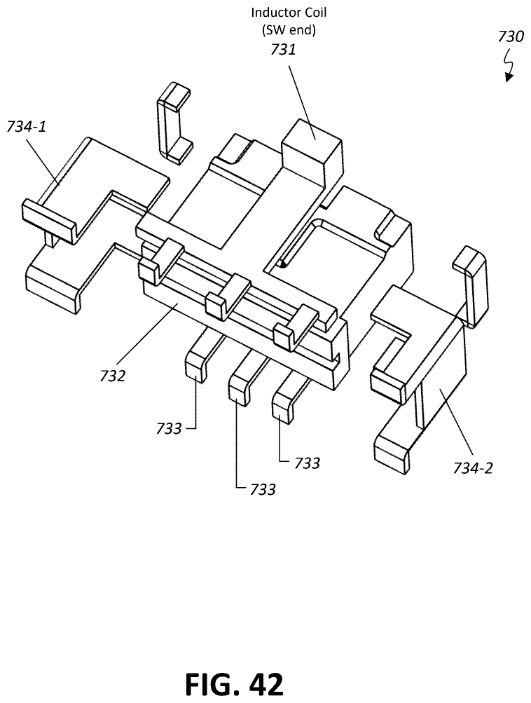

FIG. 42 shows an exploded view of the inductor structure 730, in accordance with an embodiment of the present invention. The exploded view is presented for illustrative purposes and follows the same schematic illustration conventions previously noted for exploded views. In FIG. 42, the magnetic core 732, the interconnect bars 734, and the SW end of inductor coil 731 are labeled for reference.

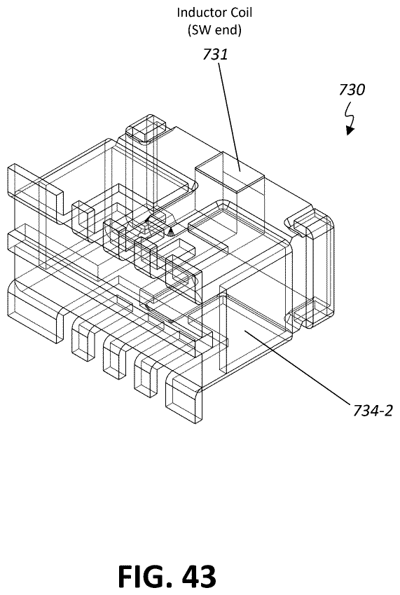

FIG. 43 shows a wireframe view of the inductor structure 730, in accordance with an embodiment of the present invention. The wireframe depiction follows the schematic illustration conventions previously noted for such views and provides an alternate perspective for viewing the outline of the components of the inductor structure 730. Labeled in FIG. 43 for reference are the SW end of inductor coil 731 and the interconnect bar 734-2.

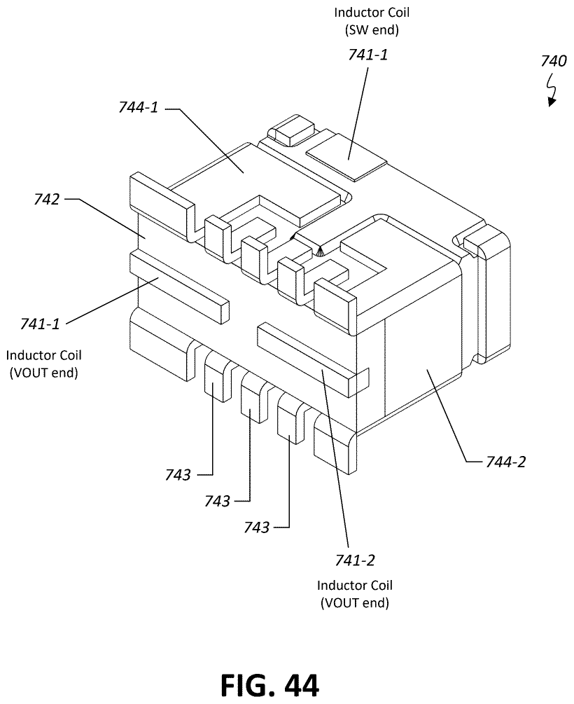

FIG. 44 shows a 3D view of an inductor structure 740, in accordance with an embodiment of the present invention. The inductor structure 740 is similar to the inductor structure 700 except that the VOUT ends of the inductor coils 741-1 and 741-2 are aligned rather than laterally offset. To accommodate the aligned VOUT end configuration, the magnetic core 742 has a modified profile compared to the magnetic core 702 of the inductor structure 700.

The inductor structure 740 includes components labeled as inductor coils 741-1 and 741-2, magnetic core 742, pads 743, and interconnect bars 744-1 and 744-2, among others. These components correspond structurally and functionally to the inductor coils 701-1 and 701-2, magnetic core 702, pads 703, and interconnect bars 704-1 and 704-2 of the inductor structure 700, except where differences are expressly noted for this embodiment. In particular, the inductor structure 740 is depicted without SW extensions on the SW ends of the inductor coils.

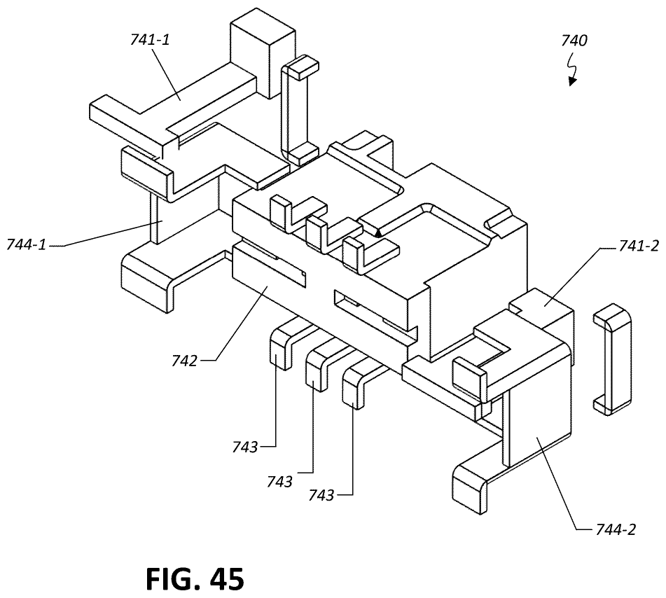

FIG. 45 shows an exploded view of the inductor structure 740, in accordance with an embodiment of the present invention. The exploded view is presented for illustrative purposes and follows the schematic illustration conventions previously noted for exploded views. In FIG. 45, various components of the inductor structure 740, including the inductor coils 741-1 and 741-2, the magnetic core 742, pads 743, and interconnect bars 744-1 and 744-2, are labeled for reference.

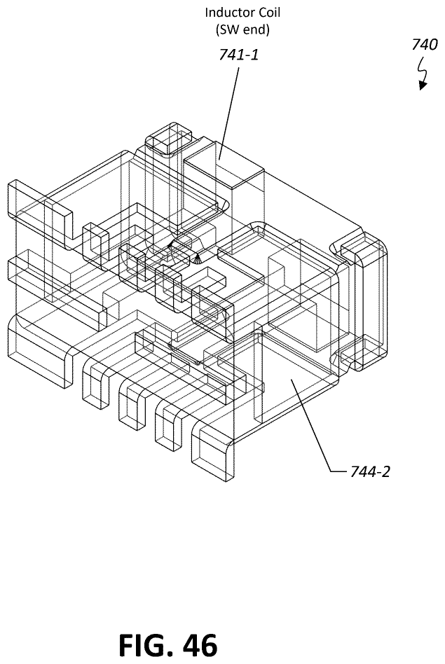

FIG. 46 shows a wireframe view of the inductor structure 740, in accordance with an embodiment of the present invention. The wireframe depiction follows the schematic illustration conventions previously noted for such views and provides an alternate perspective for viewing the outline of the components of the inductor structure 740. Labeled in FIG. 46 for reference are the SW end of inductor coil 741-1 and interconnect bar 744-2.

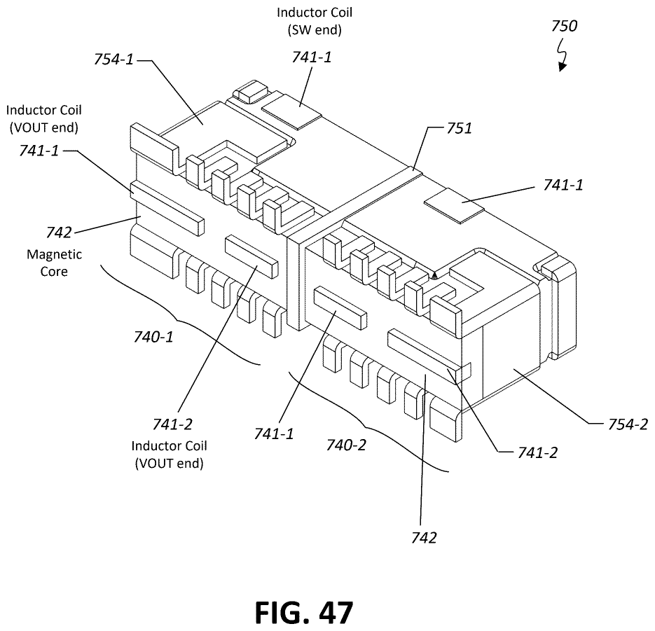

FIG. 47 shows a 3D view of an inductor structure 750, in accordance with an embodiment of the present invention. The inductor structure 750 is a four-phase inductor structure formed by joining two inductor structures 740 (i.e., inductor structures 740-1 and 740-2). In the example shown, a ground bar 751 (e.g., copper bar) is disposed between the inductor structures 740-1 and 740-2. In one embodiment, a narrow side of each inductor structure 740 that is attached to the ground bar 751 does not include an interconnect bar. Instead, interconnect bars 754 (i.e., interconnect bars 754-1 and 754-2) are disposed on opposing narrow sides of the inductor structure 750. Aside from these modifications, each inductor structure 740 in the inductor structure 750 is otherwise the same as in FIGS. 44-46.

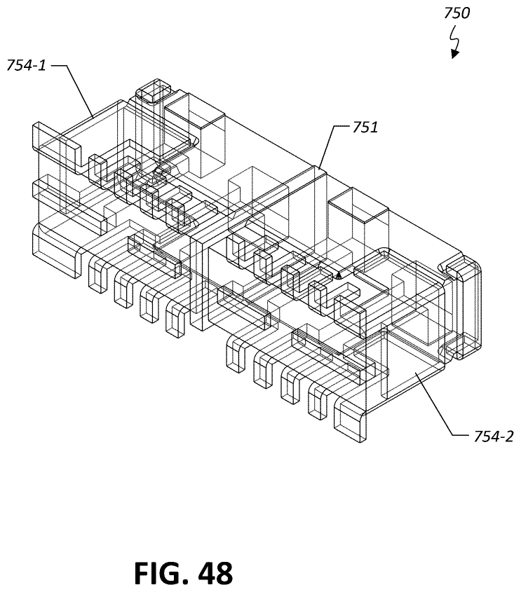

FIG. 48 shows a wireframe view of the inductor structure 750, in accordance with an embodiment of the present invention. The wireframe depiction follows the schematic illustration conventions previously noted for such views and provides an alternate perspective for viewing the outline of the components of the inductor structure 750. Labeled in FIG. 48 for reference are the ground bar 751 and the interconnect bars 754-1 and 754-2.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A power module comprising:
a first power die comprising a gate driver and a pair of transistors;
a second power die comprising a gate driver and a pair of transistors; and
an inductor structure comprising:
a first inductor coil having a first end electrically connected to an output voltage (VOUT) node and a second end electrically connected to a switch node formed by the pair of transistors of the first power die;
a second inductor coil having a first end electrically connected to the VOUT node and a second end electrically connected to a switch node formed by the pair of transistors of the second power die; and
a magnetic core shared by the first inductor coil and the second inductor coil, each of the first and second inductor coils being wound on the magnetic core one turn,
wherein the inductor structure has an outer profile defining a top side and a bottom side, and wherein the first ends of the first and second inductor coils are disposed along the bottom side and are offset from one another along a length of the bottom side.

2. The power module of claim 1, wherein the inductor structure is disposed between the first and second power dies.

3. The power module of claim 2, wherein the power module is disposed on a motherboard and each of the first and second power dies is vertically-oriented relative to a plane of the motherboard.

4. The power module of claim 1, wherein the outer profile of the inductor structure further defines opposing wide sides and opposing narrow sides, the narrow sides are narrower than the wide sides, and the second ends of the first and second inductor coils are disposed on different ones of the opposing narrow sides.

5. The power module of claim 1, further comprising a first extension that extends the second end of the first inductor coil along a corresponding narrow side of the inductor structure.

6. The power module of claim 1, wherein each of the pair of transistors of the first power die and of the second power die comprises a metal-oxide-semiconductor field-effect transistor (MOSFET).

7. The power module of claim 6, wherein each of the first and second power dies is a DrMOS module.

8. An inductor structure for a power module, the inductor structure comprising:
a first inductor coil having a first end and a second end;
a second inductor coil having a first end and a second end; and
a magnetic core shared by the first and second inductor coils, each of the first and second inductor coils being wound on the magnetic core a single turn,
wherein the inductor structure has an outer profile defining a top side and a bottom side, and wherein the first ends of the first and second inductor coils are disposed along the bottom side and are offset from one another along a length of the bottom side.

9. The inductor structure of claim 8, wherein the outer profile further defines opposing wide sides and opposing narrow sides, the narrow sides are narrower than the wide sides, and the second ends of the first and second inductor coils are disposed on different ones of the opposing narrow sides.

10. The inductor structure of claim 8 further comprising:
a first interconnect bar that is disposed on a first narrow side, extends to the opposing wide sides, and provides pads on the bottom side.

11. The inductor structure of claim 10, further comprising a second interconnect bar that is disposed on a second narrow side opposing the first narrow side, extends to the opposing wide sides, and provides pads on the bottom side.

12. A power module comprising:
a first power die comprising a gate driver and a pair of transistors;
a second power die comprising a gate driver and a pair of transistors; and
an inductor structure comprising:
a first inductor coil having a first end electrically connected to an output voltage (VOUT) node and a second end electrically connected to a switch node formed by the pair of transistors of the first power die;
a second inductor coil having a first end electrically connected to the VOUT node and a second end electrically connected to a switch node formed by the pair of transistors of the second power die; and
a magnetic core shared by the first inductor coil and the second inductor coil, each of the first and second inductor coils being wound on the magnetic core one turn,
wherein the inductor structure has an outer profile defining a top side, a bottom side, opposing wide sides, and opposing narrow sides,
wherein the narrow sides are narrower than the wide sides, the first ends of the first and second inductor coils are disposed on the bottom side, and the second ends of the first and second inductor coils are disposed on different ones of the opposing narrow sides.

13. The power module of claim 12, wherein the inductor structure is disposed between the first and second power dies.

14. The power module of claim 13, wherein the power module is disposed on a motherboard and each of the first and second power dies is vertically-oriented relative to a plane of the motherboard.

15. The power module of claim 12, further comprising a first extension that extends the second end of the first inductor coil along a corresponding narrow side of the inductor structure.

16. The power module of claim 12, wherein each of the pair of transistors of the first power die and of the second power die comprises a metal-oxide-semiconductor field-effect transistor (MOSFET).

17. The power module of claim 16, wherein each of the first and second power dies is a DrMOS module.
